(19) United States
(12) Patent Application Publication
(10) Pub. No.: US 2024/0063343 A1
(43) Pub. Date: Feb. 22, 2024

(54) DISPLAY DEVICE

(71) Applicant: Samsung Display Co., LTD., Yongin-si (KR)

(72) Inventors: Jung Hun NOH, Yongin-si (KR); Ju Won YOON, Yongin-si (KR); Jin Wan KIM, Yongin-si (KR); Jin Woo CHOI, Yongin-si (KR)

(73) Assignee: Samsung Display Co., LTD., Yongin-si (KR)

(21) Appl. No.: 18/304,455

(22) Filed: Apr. 21, 2023

(30) Foreign Application Priority Data
Aug. 16, 2022 (KR) 10-2022-0102089

(51) Int. Cl. H01L 33/38; H01L 25/16

(52) U.S. Cl. CPC H01L 33/385; H01L 25/167; H01L 33/0093

(57) ABSTRACT

A display device comprises a pixel electrode disposed on a substrate, light emitting elements disposed on the pixel electrode, a first via layer disposed on the pixel electrode and filled between the light emitting elements, and a common electrode disposed on the first via layer and the light emitting elements, wherein each of the light emitting elements includes a first semiconductor layer including a p-type dopant, an active layer disposed on the first semiconductor layer, a second semiconductor layer disposed on the active layer and including an n-type dopant, and a third semiconductor layer disposed on the second semiconductor layer, and the common electrode is in contact with a side surface of the second semiconductor layer.

### CROSS-REFERENCE TO RELATED APPLICATION(S)

This application claims priority to and benefits of Korean Patent Application No. 10-2022-0102089 under 35 U.S.C. § 119, filed on Aug. 16, 2022, in the Korean Intellectual Property Office, the entire contents of which are incorporated herein by reference.

### BACKGROUND

### 1. Technical Field

Embodiments relate to a display device and a semiconductor device.

### 2. Description of the Related Art

The importance of display devices has steadily increased with the development of multimedia technology. Various types of display devices such as an organic light emitting display (OLED), a liquid crystal display (LCD) and the like have been used.

A display device is a device for displaying an image, and includes a display panel, such as an organic light emitting display panel or a liquid crystal display panel. The light emitting display panel may include light emitting elements, e.g., light emitting diodes (LED), and examples of the light emitting diode include an organic light emitting diode (OLED) formed of an organic material as a light emitting material and an inorganic light emitting diode formed of an inorganic material as a light emitting material.

### SUMMARY

Embodiments provide a display device capable of improving the efficiency of a light emitting element.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include a pixel electrode disposed on a substrate, light emitting elements disposed on the pixel electrode, a first via layer disposed on the pixel electrode and filled between the light emitting elements, and a common electrode disposed on the first via layer and the light emitting elements, wherein each of the light emitting elements may include a first semiconductor layer including a p-type dopant, an active layer disposed on the first semiconductor layer, a second semiconductor layer disposed on the active layer and including an n-type dopant, and a third semiconductor layer disposed on the second semiconductor layer, and the common electrode may be in contact with a side surface of the second semiconductor layer.

In an embodiment, each of the light emitting elements may include an insulating layer surrounding an outer circumferential surface of each of the first semiconductor layer, the active layer, the second semiconductor layer and the third semiconductor layer, the insulating layer exposes a portion of the outer circumferential surface of the second semiconductor layer, and the common electrode may be in contact with the portion of the outer circumferential surface of the second semiconductor layer exposed by the insulating layer.

In an embodiment, in a longitudinal direction of the light emitting elements, a length of the side surface of the second semiconductor layer in contact with the common electrode may be about 10% or more of a thickness of the second semiconductor layer.

In an embodiment, the common electrode may be in contact with a top surface and a side surface of the third semiconductor layer.

In an embodiment, the display device may further include a second via layer disposed on the common electrode and filled between the light emitting elements, wherein a top surface of the second via layer and a top surface of the third semiconductor layer may be aligned with each other.

In an embodiment, the common electrode may be in contact with a side surface of the third semiconductor layer and may be spaced apart from a top surface of the third semiconductor layer.

In an embodiment, a top surface of the common electrode and the top surface of the third semiconductor layer may be aligned with each other.

In an embodiment, the common electrode may be spaced apart from the third semiconductor layer, and a top surface of the common electrode and a top surface of the second semiconductor layer may be aligned with each other.

In an embodiment, a top surface of the third semiconductor layer may include a plurality of grooves recessed toward the second semiconductor layer.

In an embodiment, the display device may further include a wavelength controller disposed on the common electrode, wherein the wavelength controller may include definition walls defining emission areas and a non-emission area, a cover layer disposed on the definition walls, and a wavelength conversion layer disposed between the definition walls and overlapping the emission areas.

In an embodiment, the definition walls may include a first definition wall and a second definition wall disposed on the first definition wall, and the first definition wall and the second definition wall include a light blocking material.

In an embodiment, the wavelength controller may include a first reflective layer disposed between the common electrode and the definition walls, and a second reflective layer disposed between the definition walls and the cover layer, and the first reflective layer and the second reflective layer overlap the non-emission area.

In an embodiment, the display device may further include a color filter layer disposed on the wavelength controller, wherein the color filter layer may include a first color filter that transmits first light, a second color filter that transmits second light, and a third color filter that transmits third light.

According to an aspect of the disclosure, a display device may include a pixel electrode disposed on a substrate, light emitting elements disposed on the pixel electrode, a first via layer disposed on the pixel electrode and filled between the light emitting elements, a common electrode disposed on the first via layer and the light emitting elements, and a first capping layer disposed on the light emitting elements and the common electrode, wherein each of the light emitting elements may include a first semiconductor layer including a p-type dopant, an active layer disposed on the first semiconductor layer, and a second semiconductor layer disposed on the active layer and including an n-type dopant, and the common electrode may be in contact with a side surface of the second semiconductor layer, and the first capping layer may be in contact with a top surface of the common electrode and a top surface of the second semiconductor layer.

In an embodiment, the display device may further include a second via layer disposed on the common electrode and filled between the light emitting elements, wherein a top surface of the second via layer and the top surface of the second semiconductor layer may be aligned with each other.

In an embodiment, the top surface of the common electrode and the top surface of the second semiconductor layer may be aligned with each other.

In an embodiment, a display device may include a pixel electrode disposed on a substrate, light emitting elements disposed on the pixel electrode, a first via layer disposed on the pixel electrode and filled between the light emitting elements, and a common electrode disposed on the first via layer and the light emitting elements, wherein each of the light emitting elements may include a first semiconductor layer including a p-type dopant, an active layer disposed on the first semiconductor layer, a second semiconductor layer disposed on the active layer and including an n-type dopant, and a third semiconductor layer disposed on the second semiconductor layer, and the common electrode may be in contact with a side surface of the second semiconductor layer, and a length of the side surface of the second semiconductor layer in contact with the common electrode may be different from a length of another side surface of the second semiconductor layer in contact with the common electrode.

In an embodiment, the display device may further include a second via layer disposed on the common electrode and filled between the light emitting elements, wherein a portion of a top surface of the third semiconductor layer may overlap the second via layer, and another portion of the top surface of the third semiconductor layer may not overlap the second via layer.

In an embodiment, the light emitting elements may include a connection electrode including a connection layer disposed between the first semiconductor layer and the pixel electrode, and a thickness of a portion of the connection layer may be different from a thickness of another portion of the connection layer.

In an embodiment, the light emitting elements may be inclined with respect to a top surface of the pixel electrode.

In accordance with the display device according to embodiments, a common electrode may be in contact with and connected to the side surface of a second semiconductor layer, so that the current flowing through a light emitting element may be induced to flow between the common electrode having a low resistance and the second semiconductor layer. Accordingly, the contact resistance between the light emitting element and the common electrode may be reduced, thereby improving the luminous efficiency of the light emitting element.

However, the effects of the disclosure are not limited to the aforementioned effects, and various other effects are included in the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment;

FIG. 2 is a schematic layout view illustrating a circuit of a display substrate of the display device according to an embodiment;

FIG. 3 is a schematic diagram of an equivalent circuit of a pixel of a display device according to an embodiment;

FIG. 4 is a schematic diagram of an equivalent circuit of a pixel of a display device according to an embodiment;

FIG. 5 is a schematic diagram of an equivalent circuit of a pixel of a display device according to an embodiment;

FIG. 6 is a schematic cross-sectional view schematically illustrating a display device according to an embodiment;

FIG. 7 is a schematic enlarged view schematically illustrating a first emission area according to an embodiment;

FIG. 8A is a schematic cross-sectional view illustrating a pixel electrode and a light emitting element according to an embodiment, FIG. 8B is a schematic diagram schematically illustrating a region of a second semiconductor layer in contact with a common electrode, and FIG. 8C is a graph showing a contact ratio and a contact area according to the contact length of the common electrode and the second semiconductor layer;

FIG. 9A is a schematic plan view illustrating an example of emission areas of a display device according to an embodiment, and FIG. 9B is a plan view illustrating another example of emission areas of a display device according to an embodiment;

FIG. 10 is a schematic plan view schematically illustrating emission areas and color filters;

FIGS. 11 to 13 are schematic plan views illustrating a modified example of emission areas of a display device according to an embodiment;

FIG. 14 is a schematic cross-sectional view schematically illustrating a display device according to an embodiment;

FIG. 15 is a schematic cross-sectional view illustrating a pixel electrode and a light emitting element according to an embodiment;

FIG. 16 is a schematic cross-sectional view schematically illustrating a display device according to an embodiment;

FIG. 17 is a schematic cross-sectional view illustrating a pixel electrode and a light emitting element according to an embodiment;

FIG. 18 is a schematic cross-sectional view illustrating a pixel electrode and a light emitting element according to an embodiment;

FIG. 19 is a schematic cross-sectional view illustrating a pixel electrode and a light emitting element according to an embodiment;

FIG. 20 is a schematic cross-sectional view illustrating a pixel electrode and a light emitting element according to an embodiment;

FIG. 21 is a schematic cross-sectional view illustrating a pixel electrode and a light emitting element according to an embodiment;

FIG. 22 is a flowchart illustrating a method of manufacturing a display device according to an embodiment;

FIGS. 23 to 45 are schematic diagrams illustrating a method of manufacturing a display device according to an embodiment;

FIG. 46 is a schematic diagram illustrating a virtual reality device including a display device according to an embodiment;

FIG. 47 is a schematic diagram illustrating a smart device including a display device according to an embodiment;

FIG. 48 is a schematic diagram illustrating an automobile including a display device according to an embodiment; and

FIG. 49 is a schematic diagram illustrating a transparent display device including a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments will be described in detail with reference to the accompanying drawings.

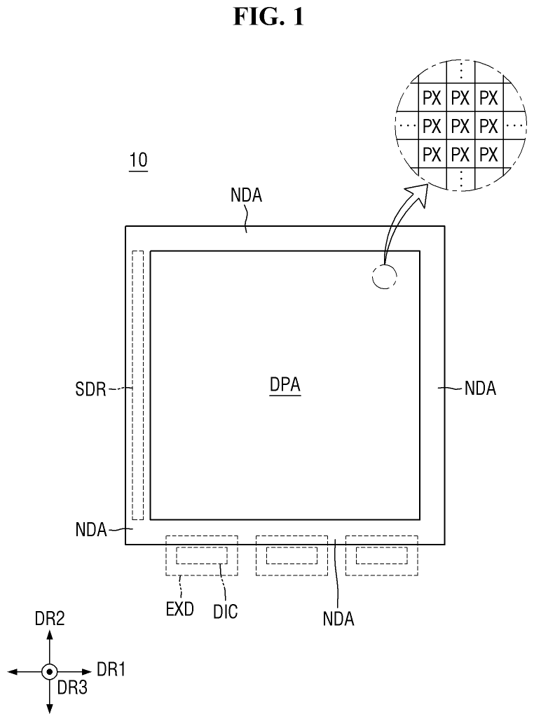

FIG. 1 is a schematic plan view of a display device according to an embodiment.

Referring to FIG. 1, a display device 10 according to an embodiment may be applied to a smartphone, a mobile phone, a tablet PC, a personal digital assistant (PDA), a portable multimedia player (PMP), a television, a game machine, a wristwatch-type electronic device, a head-mounted display, a monitor of a personal computer, a laptop computer, a car navigation system, a car's dashboard, a digital camera, a camcorder, an external billboard, an electronic billboard, a medical device, an inspection device, various household appliances such as a refrigerator and a washing machine, or an Internet-of-Things device. Herein, a television (TV) is described as an example of a display device, and the TV may have a high resolution or an ultra high resolution such as HD, UHD, 4K and 8K.

For example, the display device 10 according to an embodiment may be classified into various types according to a display method. Examples of the display device may include an organic light emitting display (OLED) device, an inorganic light emitting display (inorganic EL) device, a quantum dot light emitting display (QED) device, a micro-LED display device, a nano-LED display device, a plasma display device (PDP), a field emission display (FED) device and a cathode ray tube (CRT) display device, a liquid crystal display (LCD) device, an electrophoretic display (EPD) device, and the like. Hereinafter, the organic light emitting display device will be described as an example of the display device, and the organic light emitting display device applied to the embodiment will be simply referred to as a display device unless special distinction is required. However, the embodiment is not limited to the organic light emitting display device, and other display devices may be applied thereto.

For example, in the drawings, a first direction DR1 indicates a horizontal direction of the display device 10, a second direction DR2 indicates a vertical direction of the display device 10, and a third direction DR3 indicates a thickness direction of the display device 10. For example, “left”, “right”, “upper” and “lower” indicate directions in case that the display device 10 is viewed from above. For example, “right side” indicates a side of the first direction DR1, “left side” indicates another side of the first direction DR1, “upper side” indicates a side of the second direction DR2, and “lower side” indicates another side of the second direction DR2. Further, “upper portion” indicates a side of the third direction DR3, and “lower portion” indicates another side of the third direction DR3.

The display device 10 according to an embodiment may have a quadrate shape, e.g., a square shape in plan view. For example, in case that the display device 10 is a television, the display device 10 may have a rectangular shape with a long side positioned in the horizontal direction. However, embodiments are not limited thereto, and the long side of the display device 10 may extend in a vertical direction. In another example, the display device 10 may be implemented to be rotatable such that the long side of the display device 10 may be variably positioned to extend in the horizontal or vertical direction. Further, the display device 10 may have a circular shape or an elliptical shape.

The display device 10 may include the display area DPA and a non-display area NDA. The display area DPA may be an active area in which an image is displayed. The display area DPA may have a square shape in plan view similar to the overall shape of the display device 10, but embodiments are not limited thereto.

The display area DPA may include pixels PX. The pixels PX may be arranged in a matrix. The shape of each pixel PX may be rectangular or square in plan view. However, embodiments are not limited thereto. For example, each pixel PX may have a rhombic shape of which each side is inclined with respect to a side direction of the display device 10. The pixels PX may include multiple color pixels PX. For example, the pixels PX may include, a first color pixel PX of red, a second color pixel PX of green, and a third color pixel PX of blue. However, embodiments are not limited thereto. The color pixels PX may be alternately arranged in a stripe type or a PenTile™ type.

The non-display area NDA may be disposed around the display area DPA. The non-display area NDA may completely or partially surround the display area DPA. The display area DPA may have a square shape, and the non-display area NDA may be disposed adjacent to four sides of the display area DPA. The non-display area NDA may form a bezel of the display device 10.

In the non-display area NDA, a driving circuit or a driving element for driving the display area DPA may be disposed. In an embodiment, in the non-display area NDA disposed adjacent to a first side (lower side in FIG. 1) of the display device 10, a pad portion may be provided on a display substrate of the display device 10, and an external device EXD may be mounted on pad electrodes of the pad portion. The external devices EXD may include, e.g., a connection film, a printed circuit board, a driver integrated circuit DIC, a connector, a wiring connection film and the like. A scan driver SDR formed (e.g., directly formed) on the display substrate of the display device 10 may be provided in the non-display area NDA disposed adjacent to a second side (e.g., left side in FIG. 1) of the display device 10.

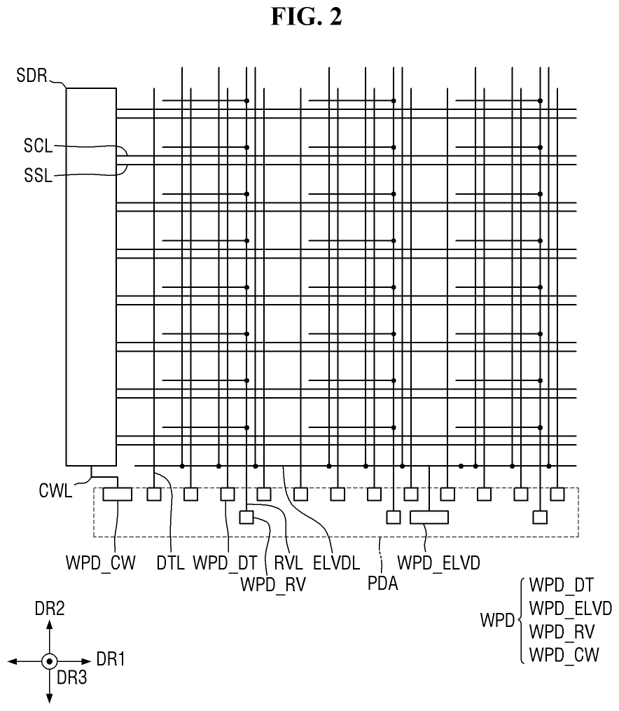

FIG. 2 is a schematic layout view illustrating a circuit of a display substrate of the display device according to an embodiment.

Referring to FIG. 2, wirings are disposed on the substrate. The wirings may include a scan line SCL, a sensing signal line SSL, a data line DTL, a reference voltage line RVL, a first power line ELVDL, and the like.

The scan line SCL and the sensing signal line SSL may extend in a first direction DR1. The scan line SCL and the sensing signal line SSL may be connected to the scan driver SDR. The scan driver SDR may include a driving circuit. The scan driver SDR may be disposed on a side of the non-display area NDA on the display substrate, but embodiments are not limited thereto, and the scan driver SDR may be disposed on sides (e.g., opposite sides) of the non-display area NDA. The scan driver SDR may be connected to a signal connection line CWL, and at least one end portion of the signal connection line CWL may be connected (e.g., electrically connected) to a pad WPD_CW on the first non-display area NDA and/or the second non-display area NDA which may be connected to the external devices (e.g., EXD in FIG. 1).

The data line DTL and the reference voltage line RVL may extend in a second direction DR2 crossing the first direction DR1. The first power line ELVDL may include portions extending in the second direction DR2. The first power line ELVDL may further include a portion extending in the first direction DR1. The first power line ELVDL may have a mesh structure, but embodiments are not limited thereto.

At least one of an end portion of the data line DTL, an end portion of the reference voltage line RVL, and an end portion of the first power line ELVDL may be connected (e.g., electrically connected) to wiring pads WPD. Each wiring pad WPD may be disposed in a pad portion PDA of the non-display area NDA. In an embodiment, a wiring pad WPD_DT (hereinafter, referred to as a data pad) of the data line DTL, a wiring pad WPD_RV (hereinafter, referred to as reference voltage pad) of the reference voltage line RVL, and a wiring pad WPD_ELVD (hereinafter, referred to as a first power pad) of the first power line ELVDL may be disposed in the pad portion PDA of the non-display area NDA. For another example, the data pad WPD_DT, the reference voltage pad WPD_RV, and the first power pad WPD_ELVD may be disposed in another non-display area NDA. As described above, the external devices (e.g., EXD in FIG. 1) may be mounted on the wiring pads WPD. The external devices EXD may be mounted on the wiring pads WPD by applying an anisotropic conductive film, ultrasonic bonding or the like.

Each pixel PX on the display substrate may include a pixel driving circuit. The above-described wirings may pass through each pixel PX (or may extend along the vicinity of each pixel PX) to apply a driving signal to each pixel driving circuit. The pixel driving circuit may include transistors and capacitors. The number of the transistors and the capacitors of each pixel driving circuit may be variously modified. Hereinafter, the pixel driving circuit will be described in conjunction with a 3T-1C structure including three transistors and one capacitor as an example. However, embodiments are not limited thereto, and other modified pixel PX structures such as a 2T-1C structure, a 7T-1C structure, and a 6T-1C structure may be adopted.

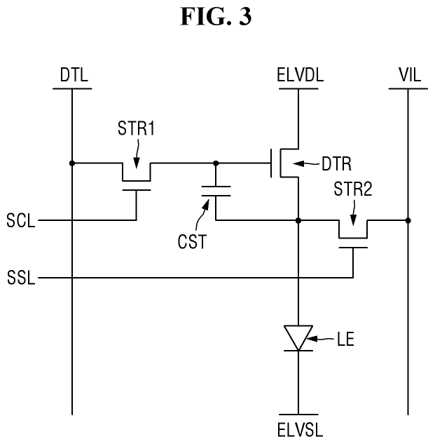

FIG. 3 is a schematic diagram of an equivalent circuit of a pixel of a display device according to an embodiment.

Referring to FIG. 3, each pixel PX of the display device according to an embodiment may include three transistors DTR, STR1 and STR2 and one storage capacitor CST in addition to a light emitting element LE.

The light emitting element LE may emit light according to a current supplied through a driving transistor DTR. The light emitting element LE may be implemented as an inorganic light emitting diode, an organic light emitting diode, a micro light emitting diode, or a nano light emitting diode.

A first electrode (e.g., anode electrode) of the light emitting element LE may be connected to a source electrode of the driving transistor DTR, and a second electrode (e.g., cathode electrode) of the light emitting element LE may be connected to a second power line ELVSL to which a low potential voltage (e.g., second source voltage) lower than a high potential voltage (e.g., first source voltage) of the first power line ELVDL is supplied.

The driving transistor DTR may adjust a current flowing from the first power line ELVDL, to which the first source voltage is applied, to the light emitting element LE according to a voltage difference between a gate electrode and the source electrode. The gate electrode of the driving transistor DTR may be connected to the first electrode of a first transistor STR1, the source electrode thereof may be connected to the first electrode of the light emitting element LE, and the drain electrode thereof may be connected to the first power line ELVDL to which the first power voltage is applied.

A first transistor STR1 may be turned on by the scan signal of a scan line SCL to connect a data line DTL to the gate electrode of the driving transistor DTR. The gate electrode of the first transistor STR1 may be connected to the scan line SCL, the first electrode thereof may be connected to the gate electrode of the driving transistor DTR, and the second electrode thereof may be connected to the data line DTL.

A second transistor STR2 may be turned on by the sensing signal of a sensing signal line SSL to connect an initialization voltage line VIL to the source electrode of the driving transistor DTR. The gate electrode of the second transistor STR2 may be connected to the sensing signal line SSL, the first electrode thereof may be connected to the initialization voltage line VIL, and the second electrode thereof may be connected to the source electrode of the driving transistor DTR.

In an embodiment, the first electrode of each of the first and second transistors STR1 and STR2 may be a source electrode and the second electrode thereof may be a drain electrode, but embodiments are not limited thereto, and may be vice versa.

The storage capacitor CST may be formed between the gate electrode and the source electrode of the driving transistor DTR. The storage capacitor CST may store a difference voltage between a gate voltage and a power voltage of the driving transistor DTR.

The driving transistor DTR, the first transistor STR1, and the second transistor STR2 may be formed as thin film transistors. Further, referring to FIG. 3, the driving transistor DTR, the first transistor STR1, and the second transistor STR2 may be N-type metal oxide semiconductor field effect transistors (MOSFETs), but embodiments are not limited thereto. For example, the driving transistor DTR, the first transistor STR1, and the second transistor STR2 may be P-type MOSFETs, or some of the driving transistor DTR, the first transistor STR1, and the second transistor STR2 may be N-type MOSFETs, while others may be P-type MOSFETs.

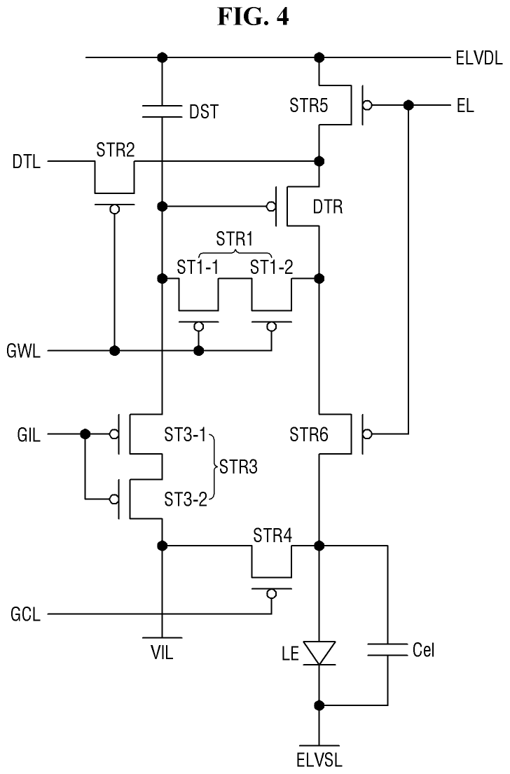

FIG. 4 is a schematic diagram of an equivalent circuit of a pixel of a display device according to an embodiment.

Referring to FIG. 4, the first electrode of the light emitting element LE may be connected to the first electrode of a fourth transistor STR4 and the second electrode of a sixth transistor STR6, and the second electrode thereof may be connected to the second power line ELVSL. A parasitic capacitance Cel may be formed between the first electrode and the second electrode of the light emitting element LE.

Each pixel PX may include the driving transistor DTR, switch elements, and the storage capacitor CST. The switch elements include first to sixth transistors STR1, STR2, STR3, STR4, STR5, and STR6.

The driving transistor DTR may include a gate electrode, a first electrode, and a second electrode. The driving transistor DTR may control a drain-source current Ids (hereinafter, referred to as driving current) flowing between the first electrode and the second electrode according to a data voltage applied to the gate electrode.

The storage capacitor CST may be formed between the second electrode of the driving transistor DTR and a second power line ELVSL. An electrode of the storage capacitor CST may be connected to the second electrode of the driving transistor DTR, and another electrode thereof may be connected to the second power line ELVSL.

In case that the first electrode of each of the driving transistor DTR and the first to sixth transistors STR1 to STR6 is a source electrode, the second electrode thereof may be a drain electrode. In another example, in case that the first electrode of each of the driving transistor DTR and the first to sixth transistors STR1 to STR6 is a drain electrode, the second electrode thereof may be a source electrode. For example, the first transistor STR1 may include at least two sub-transistors ST1-1 and ST1-2 connected to each other in series, and the third transistor STR3 may include at least two sub-transistors ST3-1 and ST3-2 connected to each other in series.

An active layer of each of the driving transistor DTR and the first to sixth transistors STR1 to STR6 may be formed of any one of polysilicon, amorphous silicon, or an oxide semiconductor. In case that a semiconductor layer of each of the driving transistor DTR and the first to sixth transistors STR1 to STR6 is formed of polysilicon, a process for forming the semiconductor layer may be a low temperature polysilicon (LTPS) process.

Further, in FIG. 4, the driving transistor DTR and the first to sixth transistors STR1 to STR6 have been described as being formed of a p-type metal oxide semiconductor field effect transistor (MOSFET), but embodiments are not limited thereto, they may be formed of an n-type MOSFET.

Furthermore, a first power voltage of the first power line ELVDL, a second power voltage of the second power line ELVSL, and a third power voltage of a third power line (e.g., initialization voltage line) VIL may be set in consideration of the characteristics of the driving transistor DTR, the characteristics of the light emitting element LE, and the like.

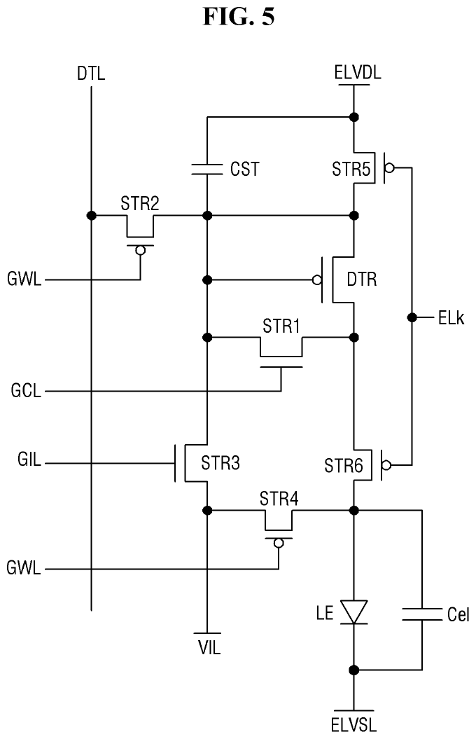

FIG. 5 is a schematic diagram of an equivalent circuit of a pixel of a display device according to an embodiment.

The embodiment of FIG. 5 is different from the embodiment of FIG. 4 in that the driving transistor DTR, the second transistor STR2, the fourth transistor STR4, the fifth transistor STR5, and the sixth transistor STR6 are formed as the P-type MOSFETs, and the first transistor STR1 and the third transistor STR3 are formed as the N-type MOSFETs.

Referring to FIG. 5, an active layer of each of the driving transistor DTR, the second transistor STR2, the fourth transistor STR4, the fifth transistor STR5 and the sixth transistor STR6 implemented as the P-type MOSFETs may be formed of polysilicon, whereas an active layer of each of the first transistor STR1 and the third transistor STR3 implemented as the N-type MOSFETs may be formed of an oxide semiconductor.

The embodiment of FIG. 5 is different from the embodiment of FIG. 4 in that the gate electrode of the second transistor STR2 and the gate electrode of the fourth transistor STR4 are connected to a write scan line GWL, and the gate electrode of the first transistor STR1 is connected to a control scan line GCL. Further, in FIG. 5, since the first transistor STR1 and the third transistor STR3 are formed as the N-type MOSFET, the scan signal of a gate high voltage may be applied to the control scan line GCL and an initialization scan line GIL. For example, the second transistor STR2, the fourth transistor STR4, the fifth transistor STR5, and the sixth transistor STR6 may be formed as the P-type MOSFETs, so that a scan signal of a gate low voltage may be applied to the write scan line GWL and an emission line EL.

For example, the equivalent circuit of the pixel according to the above-described embodiment is not limited to those illustrated in FIGS. 3 to 5. The equivalent circuit of the pixel according to the embodiment may be formed in various circuit structures in addition to the embodiments illustrated in FIGS. 3 to 5.

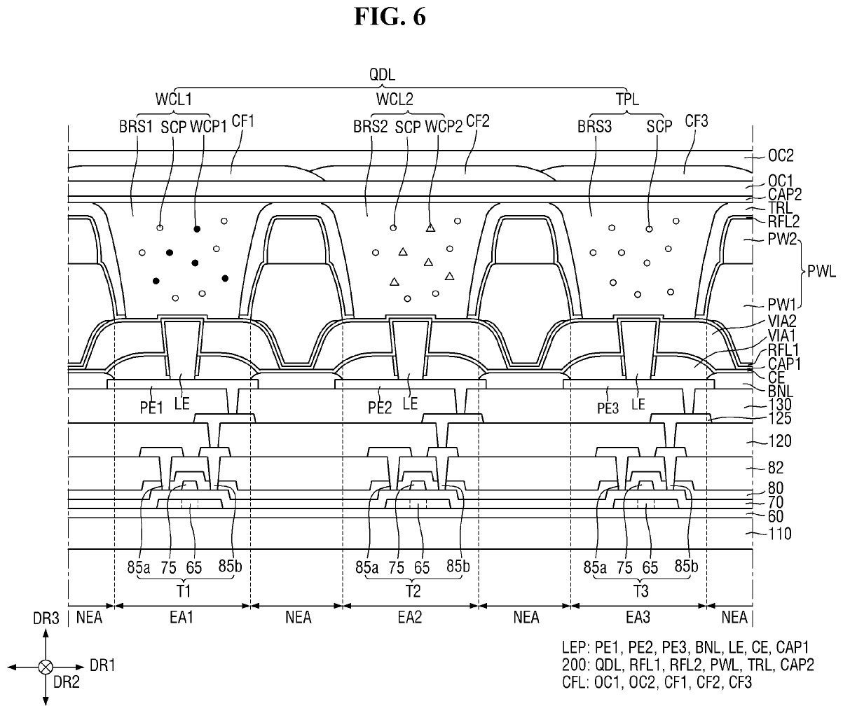

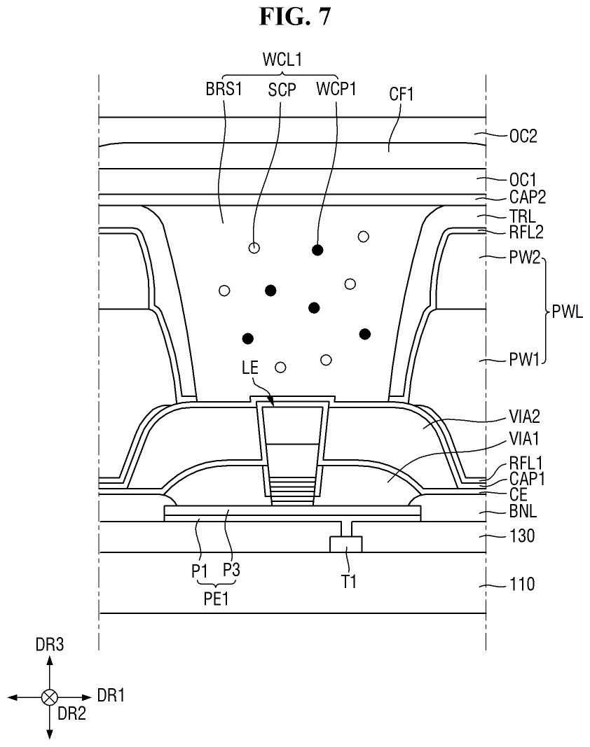

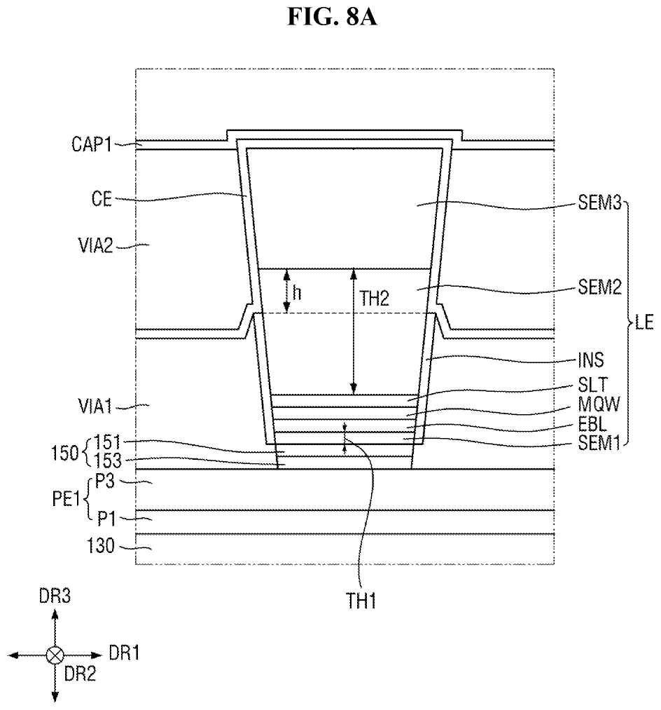

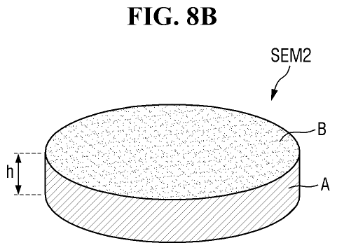

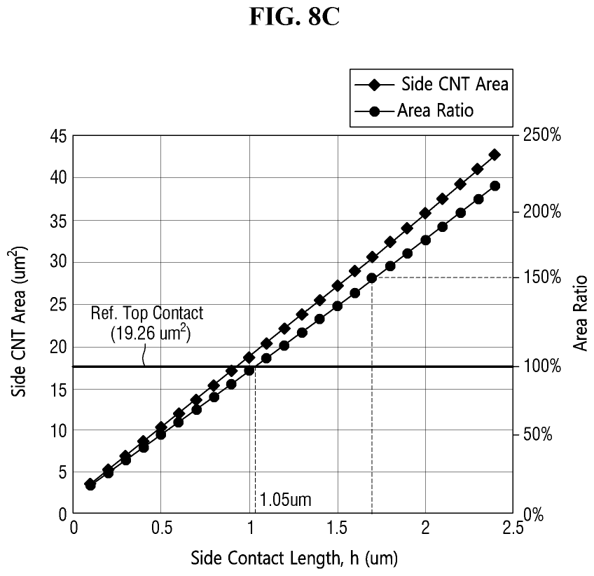

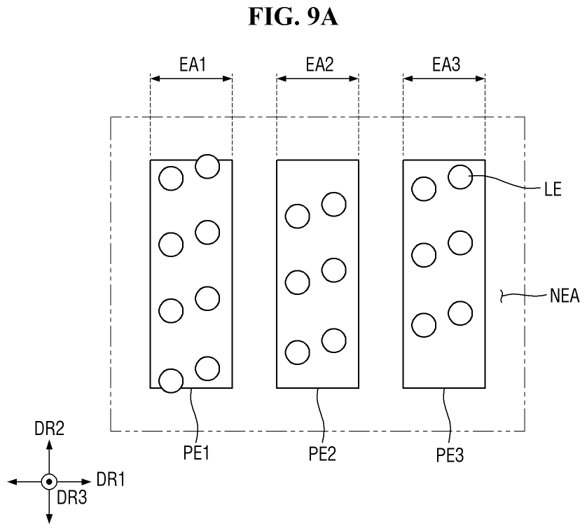

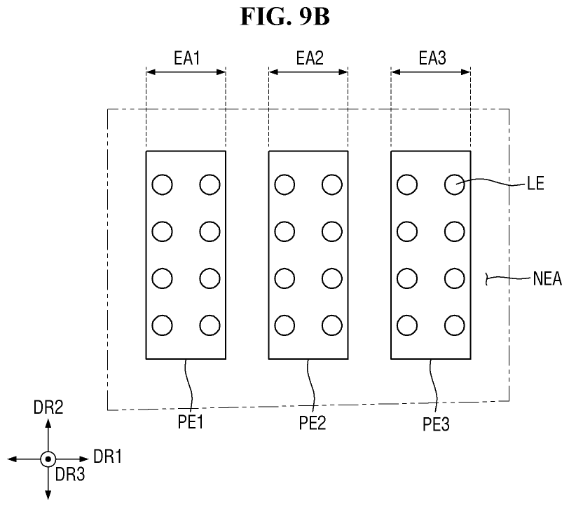

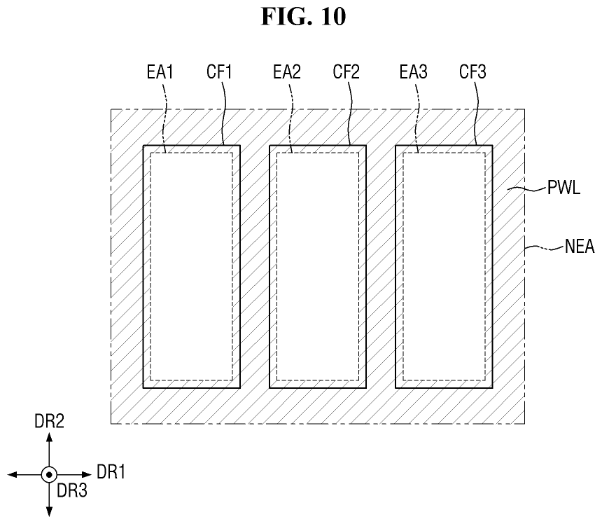

FIG. 6 is a schematic cross-sectional view schematically illustrating a display device according to an embodiment. FIG. 7 is a schematic enlarged view schematically illustrating a first emission area according to an embodiment. FIG. 8A is a schematic cross-sectional view illustrating a pixel electrode and a light emitting element according to an embodiment, FIG. 8B is a schematic diagram schematically illustrating a region of a second semiconductor layer in contact with a common electrode, and FIG. 8C is a graph showing a contact ratio and a contact area according to the contact length of the common electrode and the second semiconductor layer. FIG. 9A is a schematic plan view illustrating an example of emission areas of a display device according to an embodiment, and FIG. 9B is a schematic plan view illustrating another example of emission areas of a display device according to an embodiment. FIG. 10 is a schematic plan view schematically illustrating emission areas and color filters. FIGS. 11 to 13 are schematic plan views illustrating a modified example of emission areas of a display device according to an embodiment.

Referring to FIGS. 6 to 13, the display device 10 may include a display substrate 100, and a wavelength controller 200 and a color filter layer CFL that are disposed on the display substrate 100.

The display substrate 100 may include a substrate 110 and a light emitting element unit LEP disposed on the substrate 110. The substrate 110 may be an insulating substrate. The substrate 110 may include a transparent material. For example, the substrate 110 may include a transparent insulating material such as glass, quartz, or the like. The substrate 110 may be a rigid substrate. However, embodiments are not limited thereto. The substrate 110 may include plastic such as polyimide or the like, and may have a flexible property such that the substrate 110 may be twisted, bent, folded, or rolled. Emission areas EA1, EA2, and EA3 and a non-emission area NEA may be defined in the substrate 110.

Switching elements T1, T2, and T3 may be positioned on the substrate 110. In an embodiment, the first switching element T1 may be positioned in the first emission area EA1 of the substrate 110, the second switching element T2 may be positioned in the second emission area EA2 thereof, and the third switching element T3 may be positioned in the third emission area LA3 thereof. However, embodiments are not limited thereto, and in another example, at least one of the first switching element T1, the second switching element T2 and the third switching element T3 may be disposed in the non-emission area NEA.

In an embodiment, each of the first switching element T1, the second switching element T2, and the third switching element T3 may be a thin film transistor including amorphous silicon, polysilicon, or an oxide semiconductor. For example, signal lines (e.g., a gate line, a data line, a power line, and the like) that transmit signals to the switching elements may be further positioned on the substrate 110.

Each of the switching elements T1, T2, and T3 may include a semiconductor layer 65, a gate electrode 75, a source electrode 85a, and a drain electrode 85b. For example, a buffer layer 60 may be disposed on the substrate 110. The buffer layer 60 may cover (e.g., entirely cover) the surface of the substrate 110. The buffer layer 60 may include silicon nitride, silicon oxide, or silicon oxynitride, and may be formed as a single layer or a double layer thereof.

The semiconductor layer 65 may be disposed on the buffer layer 60. The semiconductor layer 65 may form a channel of each of the switching elements T1, T2, and T3. The semiconductor layer 65 may include amorphous silicon, polycrystalline silicon, or an oxide semiconductor. As an example, the oxide semiconductor may include, for example, a binary compound (ABₓ), a ternary compound (ABₓC_{y}), or a quaternary compound (ABₓC_{y}D_{z}) including indium, zinc, gallium, tin, titanium, aluminum, hafnium (Hf), zirconium (Zr), magnesium (Mg) and the like. In an embodiment, the semiconductor layer 65 may include indium tin zinc oxide (IGZO).

A gate insulating layer 70 may be disposed on the semiconductor layer 65. The gate insulating layer 70 may include a silicon compound, a metal oxide, or the like. For example, the gate insulating layer 70 may include silicon oxide, silicon nitride, silicon oxynitride, aluminum oxide, tantalum oxide, hafnium oxide, zirconium oxide, titanium oxide, or the like. In an embodiment, the gate insulating layer 70 may include silicon oxide.

The gate electrode 75 may be disposed on the gate insulating layer 70. The gate electrode 75 may overlap the semiconductor layer 65. The gate electrode 75 may include a conductive material. The gate electrode 75 may include a metal oxide such as ITO, IZO, ITZO, and In₂O₃ or a metal such as copper (Cu), titanium (Ti), aluminum (Al), molybdenum (Mo), tantalum (Ta), calcium (Ca), chromium (Cr), magnesium (Mg), and nickel (Ni). For example, the gate electrode 75 may be formed as a Cu/Ti double layer in which an upper layer made of copper is stacked on a lower layer made of titanium, but embodiments are not limited thereto.

A first interlayer insulating layer 80 and a second interlayer insulating layer 82 may be disposed on the gate electrode 75. The first interlayer insulating layer 80 may be disposed (e.g., directly disposed) on the gate electrode 75, and the second interlayer insulating layer 82 may be disposed (e.g., directly disposed) on the first interlayer insulating layer 80. Each of the first interlayer insulating layer 80 and the second interlayer insulating layer 82 may include an inorganic insulating material such as silicon oxide, silicon nitride, silicon oxynitride, hafnium oxide, aluminum oxide, titanium oxide, tantalum oxide, zinc oxide, or the like. However, embodiments are not limited thereto, and the second interlayer insulating layer 82 may include an organic insulating material capable of flattening a stepped portion disposed thereunder.

The source electrode 85a and the drain electrode 85b may be disposed on the second interlayer insulating layer 82. The source electrode 85a and the drain electrode 85b may be in contact with the semiconductor layer 65 through contact holes penetrating the first interlayer insulating layer 80, the second interlayer insulating layer 82, and the gate insulating layer 70. The source electrode 85a and the drain electrode 85b may include a metal oxide such as ITO, IZO, ITZO, and In₂O₃ or a metal such as copper (Cu), titanium (Ti), aluminum (Al), molybdenum (Mo), tantalum (Ta), calcium (Ca), chromium (Cr), magnesium (Mg), and nickel (Ni). For example, the source electrode 85a and the drain electrode 85b may be formed as a Cu/Ti double layer in which an upper layer made of copper is stacked on a lower layer made of titanium, but embodiments are not limited thereto.

A first planarization layer 120 may be disposed on the first switching element T1, the second switching element T2, and the third switching element T3. The first planarization layer 120 may include an organic material. For example, the first planarization layer 120 may include acrylic resin, epoxy resin, imide resin, ester resin, or the like. In an embodiment, the first planarization layer 120 may include a positive photosensitive material or a negative photosensitive material.

A pixel connection electrode 125 may be disposed on the first planarization layer 120. The pixel connection electrode 125 may correspond to (e.g., overlap) each of the first switching element T1, the second switching element T2, and the third switching element T3, and may be electrically connected thereto. The pixel connection electrode 125 may connect pixel electrodes PE1, PE2, and PE3 to be described below to the above-described switching elements T1, T2, and T3. The pixel connection electrode 125 may be in contact with the switching elements T1, T2, and T3 through contact holes penetrating the first planarization layer 120.

A second planarization layer 130 may be disposed on the first planarization layer 120 and the pixel connection electrode 125. The second planarization layer 130 may flatten a stepped portion disposed thereunder. The first planarization layer 120 and the second planarization layer 130 may include the same material.

The light emitting element unit LEP may be disposed on the second planarization layer 130. The light emitting element unit LEP may include the pixel electrodes PE1, PE2, and PE3, the light emitting elements LE, and the common electrode CE. For example, the light emitting element unit LEP may further include a bank layer BNL that partitions (or defines) the emission areas EA1, EA2, and EA3, and a first via layer VIA1 and a second via layer VIA2.

The pixel electrodes PE1, PE2, and PE3 may include the first pixel electrode PE1, the second pixel electrode PE2, and the third pixel electrode PE3. The first pixel electrode PE1, the second pixel electrode PE2, and the third pixel electrode PE3 may function as the first electrode of the light emitting element LE, and may be an anode electrode or a cathode electrode. The first pixel electrode PE1 may be disposed in the first emission area EA1, the second pixel electrode PE2 may be disposed in the second emission area EA2, and the third pixel electrode PE3 may be disposed in the third emission area EA3. In an embodiment, the first pixel electrode PE1 may overlap (e.g., completely overlap) the first emission area EA1, the second pixel electrode PE2 may overlap (e.g., completely overlap) the second emission area EA2, and the third pixel electrode PE3 may overlap (e.g., completely overlap) the third emission area EA3.

The pixel electrodes PE1, PE2, and PE3 may be connected (e.g., directly connected) to the pixel connection electrode 125 through the contact holes penetrating the second planarization layer 130, and may be electrically connected to the switching elements T1, T2, and T3 through the pixel connection electrode 125, respectively. The first pixel electrode PE1, the second pixel electrode PE2, and the third pixel electrode PE3 may include a metal. The metal may include, e.g., copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. Further, the first pixel electrode PE1, the second pixel electrode PE2, and the third pixel electrode PE3 may have a multi-layer structure in which two or more metal layers are stacked. For example, the first pixel electrode PE1, the second pixel electrode PE2, and the third pixel electrode PE3 may have a two-layer structure in which a copper layer is stacked on a titanium layer, but embodiments are not limited thereto.

Referring to FIG. 7, in an embodiment, each of the pixel electrodes PE1, PE2, and PE3 may include a lower electrode layer P1 and an upper electrode layer P3. Hereinafter, the first pixel electrode PE1 will be described as an example.

The lower electrode layer P1 may be disposed at the lowermost portion of the first pixel electrode PE1 and may be electrically connected from the switching element. The lower electrode layer P1 may function to provide adhesiveness with the second planarization layer 130 to the first pixel electrode PE1. The lower electrode layer P1 may include a metal, e.g., titanium.

The upper electrode layer P3 may be disposed on the lower electrode layer P1 to be in contact with (e.g., in direct contact with) the light emitting element LE. The upper electrode layer P3 may be disposed between the lower electrode layer P1 and the light emitting element LE, and may function to provide adhesiveness with the light emitting element LE to the first pixel electrode PE1. The upper electrode layer P3 may include a metal, e.g., copper.

The light emitting elements LE may be disposed on the first pixel electrode PE1, the second pixel electrode PE2, and the third pixel electrode PE3.

As illustrated in FIGS. 6 to 8A, the light emitting elements LE may be disposed in each of the first emission area EA1, the second emission area EA2, and the third emission area EA3. The light emitting element LE may be a vertical light emitting diode element elongated in the third direction DR3. For example, the length of the light emitting element LE in the third direction DR3 may be longer than the length thereof in the horizontal direction. The length in the horizontal direction indicates a length in the first direction DR1 or a length in the second direction DR2. For example, the length of the light emitting element LE in the third direction DR3 may be about 1 to about 5 μm.

The light emitting element LE may be a micro light emitting diode element. The light emitting element LE may include a connection electrode 150, a first semiconductor layer SEM1, an electron blocking layer EBL, an active layer MQW, a superlattice layer SLT, a second semiconductor layer SEM2, and a third semiconductor layer SEM3, in the thickness direction of the display substrate 100, e.g., the third direction DR3. The connection electrode 150, the first semiconductor layer SEM1, the electron blocking layer EBL, the active layer MQW, the superlattice layer SLT, the second semiconductor layer SEM2, and the third semiconductor layer SEM3 may be sequentially stacked in the third direction DR3. However, embodiments are not limited thereto, and the electron blocking layer EBL and the superlattice layer SLT may be replaced with other layers or may be omitted. The light emitting element LE may include an insulating layer INS surrounding the first semiconductor layer SEM1, the electron blocking layer EBL, the active layer MQW, the superlattice layer SLT, the second semiconductor layer SEM2, and at least a portion of the third semiconductor layer SEM3.

The light emitting element LE may have a cylindrical shape that is longer in width than in height, a disc shape, or a rod shape. However, embodiments are not limited thereto, and the light emitting element LE may have various shapes, such as a rod shape, a wire shape, a tube shape, a polygonal prism shape such as a regular cube, a rectangular parallelepiped and a hexagonal prism, or a shape extending in a direction and having a partially inclined outer surface.

The connection electrode 150 may be disposed on each of the pixel electrodes PE1, PE2, and PE3. Hereinafter, the light emitting element LE disposed on the first pixel electrode PE1 will be described as an example, but embodiments are not limited thereto, and the light emitting elements LE disposed on the second pixel electrode PE2 and the third pixel electrode PE3 may have the same structure.

The connection electrode 150 may include a reflective layer 151 and a connection layer 153. The reflective layer 151 may function to reflect light emitted from the active layer MQW of the light emitting element LE. The reflective layer 151 may be disposed adjacent to the active layer MQW of the light emitting element LE. The reflective layer 151 may include a metal material having conductivity and high light reflectivity. The reflective layer 151 may include, e.g., aluminum (Al) or silver (Ag), or an alloy thereof.

The connection layer 153 may function to transmit an emission signal from the first pixel electrode PE1 to the light emitting element LE. The connection layer 153 may be an ohmic connection electrode. However, embodiments are not limited thereto, and the connection layer 153 may be a Schottky connection electrode. The connection layer 153 may be disposed at the lowermost end portion of the light emitting element LE, and may be more distant from the active layer MQW than the reflective layer 151. The connection layer 153 may include at least one of gold (Au), copper (Cu), tin (Sn), silver (Ag), aluminum (Al), or titanium (Ti). For example, the connection layer 153 may include a 9:1 alloy, an 8:2 alloy or a 7:3 alloy of gold and tin, or may include an alloy (SAC305) of copper, silver, and tin.

Although FIG. 8A illustrates the connection electrode 150 in which the light emitting element LE has a double-layer structure of one reflective layer 151 and the connection layer 153, embodiments are not limited thereto. In some cases, the light emitting element LE may include the connection electrode 150 in which a larger number of layers are stacked, or some layers may be omitted.

The first semiconductor layer SEM1 may be disposed on the connection electrode 150. The first semiconductor layer SEM1 may be a p-type semiconductor, and may include a semiconductor material having a chemical formula of AlₓGa_{y}In_{1-x-y}N (0≤x≤1, 0≤y≤1, 0≤x+y≤1). For example, the semiconductor material may be any one or more of p-type doped AlGaInN, GaN, AlGaN, InGaN, AlN and InN. The first semiconductor layer SEM1 may be doped with a p-type dopant, and the p-type dopant may be Mg, Zn, Ca, Se, Ba, or the like. For example, the first semiconductor layer SEM1 may be p-GaN doped with p-type Mg. The thickness TH1 of the first semiconductor layer SEM1 may be in a range of about 30 nm to about 200 nm, but embodiments are not limited thereto.

The electron blocking layer EBL may be disposed on the first semiconductor layer SEM1. The electron blocking layer EBL may be a layer for suppressing or preventing too many electrons from flowing into the active layer MQW. For example, the electron blocking layer EBL may be p-AlGaN doped with p-type Mg. The thickness of the electron blocking layer EBL may be within a range of about 10 nm to about 50 nm, but embodiments are not limited thereto. In another example, the electron blocking layer EBL may be omitted.

The active layer MQW may be disposed on the electron blocking layer EBL. The active layer MQW may emit light by coupling of electron-hole pairs according to an electrical signal applied through the first semiconductor layer SEM1 and the second semiconductor layer SEM2. The active layer MQW may emit first light having a central wavelength band of about 450 nm to about 495 nm, e.g., light of a blue wavelength band.

The active layer MQW may include a material having a single quantum well structure or multiple quantum well structure. In case that the active layer MQW includes a material having a multiple quantum well structure, the active layer MQW may have the structure in which well layers and barrier layers are alternately laminated. For example, the well layer may be formed of InGaN, and the barrier layer may be formed of GaN or AlGaN, but embodiments are not limited thereto. The thickness of the well layer may be about 1 to about 4 nm, and the thickness of the barrier layer may be about 3 nm to about 10 nm.

In another example, the active layer MQW may have a structure in which semiconductor materials having large band gap energy and semiconductor materials having small band gap energy are alternately stacked, and may include other group III to V semiconductor materials according to the wavelength band of the emitted light. The light emitted by the active layer MQW is not limited to the first light, and in some cases, the second light (light of the green wavelength band) or the third light (light of the red wavelength band) may be emitted. In an embodiment, in case that the semiconductor materials included in the active layer MQW may include indium, the color of emitted light may vary according to the content of indium. For example, in case that the content of indium is about 15%, light of the blue wavelength band may be emitted, in case that the content of indium is about 25%, light of the green wavelength band may be emitted, and in case that the content of indium is about 35% or more, light of the red wavelength band may be emitted.

The superlattice layer SLT may be disposed on the active layer MQW. The superlattice layer SLT may be a layer for relieving (or reducing) stress between the second semiconductor layer SEM2 and the active layer MQW. For example, the superlattice layer SLT may be formed of InGaN or GaN. The thickness of the superlattice layer SLT may be about 50 nm to about 200 nm. In another example, the superlattice layer SLT may be omitted.

The second semiconductor layer SEM2 may be disposed on the superlattice layer SLT. The second semiconductor layer SEM2 may be an n-type semiconductor. The second semiconductor layer SEM2 may include a semiconductor material having a chemical formula of AlₓGa_{y}In_{1-x-y}N (0≤x≤1, 0≤y≤1, 0≤x+y≤1). For example, the semiconductor material may be any one or more of n-type doped AlGaInN, GaN, AlGaN, InGaN, AlN and InN. The second semiconductor layer SEM2 may be doped with an n-type dopant, and the n-type dopant may be Si, Ge, Sn, or the like. For example, the second semiconductor layer SEM2 may be n-GaN doped with n-type Si. The thickness TH2 of the second semiconductor layer SEM2 may be within a range of about 2 μm to about 4 μm, but embodiments are not limited thereto.

The third semiconductor layer SEMS may be disposed on the second semiconductor layer SEM2. The third semiconductor layer SEM3 may be disposed between the second semiconductor layer SEM2 and the common electrode CE. The third semiconductor layer SEM3 may be an undoped semiconductor. The second semiconductor layer SEM2 and the third semiconductor layer SEM3 may include the same material. The third semiconductor layer SEM3 may include a material that is not doped with an n-type or p-type dopant. In an embodiment, the third semiconductor layer SEM3 may be at least one of undoped InAlGaN, GaN, AlGaN, InGaN, AlN, or InN, but embodiments are not limited thereto.

The insulating layer INS may surround the side surfaces of the light emitting element LE, e.g., the outer circumferential surfaces thereof. The insulating layer INS may insulate the light emitting elements LE from other layers. The insulating layer INS may be disposed (e.g., directly disposed) on the outer circumferential surfaces of the first semiconductor layer SEM1, the second semiconductor layer SEM2, the superlattice layer SLT, the active layer MQW, and the electron blocking layer EBL to surround them. In an embodiment, the insulating layer INS may surround the entire outer circumferential surfaces of the first semiconductor layer SEM1, the superlattice layer SLT, the active layer MQW, and the electron blocking layer EBL, and may surround a portion of the outer circumferential surface of the second semiconductor layer SEM2. In case that a portion of the second semiconductor layer SEM2 is exposed by the insulating layer INS, the common electrode CE to be described below may be in contact with (e.g., in direct contact with) and connected to the second semiconductor layer SEM2.

As shown in FIG. 8A, the insulating layer INS may surround the light emitting elements LE. The insulating layer INS may include an inorganic insulating material such as silicon oxide (SiOₓ), silicon nitride (SiNₓ), silicon oxynitride (SiOₓN_{y}), aluminum oxide (AlₓO_{y}), and aluminum nitride (AlN). The thickness of the insulating layer INS may be about 0.1 μm, but embodiments are not limited thereto.

The first via layer VIA1 may be disposed on the pixel electrodes PE1, PE2, and PE3 and the second planarization layer 130. The first via layer VIA1 may flatten the stepped portion disposed thereunder so that the common electrode CE to be described below may be formed. The first via layer VIA1 may have a certain height so that at least a portion of the light emitting elements LE, e.g., the second semiconductor layer SEM2 and the third semiconductor layer SEM3, may protrude upward from the first via layer VIA1. For example, the height of the first via layer VIA1 with respect to the top surface of the first pixel electrode PE1 may be smaller than the height of the light emitting element LE.

In an embodiment, the height of the first via layer VIA1 may be lower than the height of the second semiconductor layer SEM2 of the light emitting element LE. In a process to be described below, the first via layer VIA1 may be formed, and the insulating layer INS may be etched by using the first via layer VIA1 as a mask. Since the second semiconductor layer SEM2 needs to be in contact with the common electrode CE, the first via layer VIA1 may have a height lower than the height of the second semiconductor layer SEM2 so that the insulating layer INS may expose the second semiconductor layer SEM2. The first via layer VIA1 may have a height lower than the height of the second semiconductor layer SEM2 and higher than the height of the active layer MQW, thereby preventing the active layer MQW from being damaged by an etchant.

The first via layer VIA1 may include an organic material to flatten the stepped portion disposed thereunder. For example, the first via layer VIA1 may include acrylic resin, epoxy resin, phenolic resin, polyamide resin, polyimide resin, unsaturated polyester resin, polyphenylene resin, polyphenylenesulfide resin, benzocyclobutene (BCB), or the like.

The common electrode CE may be disposed on the first via layer VIA1 and the light emitting elements LE. For example, the common electrode CE may be disposed on a surface of the substrate 110 on which the light emitting element LE is formed, and may be disposed (e.g., entirely disposed) in the display area DPA and the non-display area NDA. The common electrode CE may be disposed to overlap each of the emission areas EA1, EA2, and EA3 in the display area DPA, and may have a thin thickness to allow light to be emitted.

The common electrode CE may be disposed (e.g., directly disposed) on the top surface and the side surface of the light emitting elements LE. The common electrode CE may be in contact with (e.g., in direct contact with) the second semiconductor layer SEM2 and the third semiconductor layer SEM3 among the side surfaces of the light emitting element LE. As illustrated in FIG. 8, the common electrode CE may be a common layer that covers the light emitting elements LE and is disposed by commonly connecting the light emitting elements LE. Since the second semiconductor layer SEM2 having conductivity has a patterned structure in each of the light emitting elements LE, the common electrode CE may be in contact with (e.g., in direct contact with) the side surface of the second semiconductor layer SEM2 of each of the light emitting elements LE so that a common voltage may be applied to each of the light emitting elements LE.

In an embodiment, the common electrode CE may be in contact with (e.g., in direct contact with) the side surface of the second semiconductor layer SEM2 of each light emitting element LE. The contact resistance between the common electrode CE and the second semiconductor layer SEM2 may be considerably lower than the contact resistance between the common electrode CE and the third semiconductor layer SEM3. This is because the third semiconductor layer SEM3 does not include a dopant and has poor conductivity, whereas the second semiconductor layer SEM2 includes an N-type dopant and has excellent conductivity. Accordingly, the common electrode CE may be in contact with the side surface of the second semiconductor layer SEM2. Thus, the current flowing through the light emitting element LE may be induced to flow between the common electrode CE having a low resistance and the second semiconductor layer SEM2, thereby improving the luminous efficiency of the light emitting element LE.

Referring to FIGS. 8A and 8B, a length h in the third direction DR3 of the second semiconductor layer SEM2 in contact with the common electrode CE may be about 10% or more of the thickness TH2 of the second semiconductor layer SEM2 in the third direction DR3. For example, the third direction DR3 may correspond to the longitudinal direction of the light emitting element LE. It means that the contact area between the common electrode CE and the second semiconductor layer SEM2 increases as the lengths of the common electrode CE and the second semiconductor layer SEM2 in the third direction DR3 increase. In case that the contact area between the common electrode CE and the second semiconductor layer SEM2 increases, current movement between the common electrode CE and the second semiconductor layer SEM2 is facilitated, thereby improving the luminous efficiency. For example, the length in the third direction DR3 of the second semiconductor layer SEM2 in contact with the common electrode CE may be about 30% or more of the thickness TH2 of the second semiconductor layer SEM2 in the third direction DR3, and may be about 50% or more thereof. In an embodiment, the length h in the third direction DR3 of the second semiconductor layer SEM2 in contact with the common electrode CE may be about 1.05 μm or more. However, embodiments are not limited thereto.

Referring to FIGS. 8B and 8C, the length h in the third direction DR3 of the second semiconductor layer SEM2 in contact with the common electrode CE may be proportional to a contact area A of the second semiconductor layer SEM2 in contact with the common electrode CE. The contact area A in which the common electrode CE is in side contact with the side surface of the second semiconductor layer SEM2 may further improve the contact area compared to a contact area B where the common electrode CE is in top contact with the top surface of the second semiconductor layer SEM2. For example, in case that the length h in the third direction DR3 of the second semiconductor layer SEM2 in contact with the common electrode CE is about 1.05 μm or more, the contact area A may become the same as the contact area where the contact electrode CE is in contact with the top surface of the second semiconductor layer SEM2. Further, in case that the length h in the third direction DR3 of the second semiconductor layer SEM2 in contact with the common electrode CE is about 1.7 μm or more, the contact area A may be increased by about 1.5 times compared to the contact area where the common electrode CE is in contact with the top surface of the second semiconductor layer SEM2. Accordingly, the common electrode CE may be in contact with the side surface of the second semiconductor layer SEM2, thereby reducing the contact resistance and improving the efficiency of the light emitting element LE.

For example, since the common electrode CE is entirely disposed on the substrate 110 and a common voltage is applied, the common electrode CE may include a material having a low resistance. For example, the common electrode CE may have a thin thickness to transmit light therethrough. For example, the common electrode CE may include a metal material having a low resistance, such as aluminum (Al), silver (Ag), copper (Cu), or the like, or a metal oxide such as ITO, IZO, ITZO, or the like. The thickness of the common electrode CE may be about 10 Å to about 200 Å, but embodiments are not limited thereto.

The above-described light emitting elements LE may receive a pixel voltage or an anode voltage from each of the pixel electrodes PE1, PE2, and PE3, and may receive a common voltage through the common electrode CE. The light emitting elements LE may emit light with a certain luminance according to a voltage difference between the pixel voltage and the common voltage. In an embodiment, by disposing the light emitting elements LE, e.g., inorganic light emitting diodes on the pixel electrodes PE1, PE2, and PE3, the disadvantages of organic light emitting diodes, which are vulnerable to external moisture or oxygen, may be excluded (or solved), and lifespan and reliability may be improved.

As illustrated in FIG. 9A, the light emitting elements LE may be disposed on each of the pixel electrodes PE1, PE2, and PE3. The light emitting elements LE may be regularly arranged according to a certain rule. For example, the light emitting elements LE may be spaced apart from each other by regular intervals (or constant distances). However, embodiments are not limited thereto, and the light emitting elements LE may be irregularly arranged.

Further, as illustrated in FIG. 9B, the light emitting elements LE may be disposed on each of the pixel electrode PE1, PE2, and PE3 to be spaced apart from each other by the same interval. For example, any one light emitting element LE may be spaced apart from adjacent light emitting elements LE by the same interval.

The light emitting elements LE may be generally disposed on each of the pixel electrodes PE1, PE2, and PE3. However, embodiments are not limited thereto, and some light emitting elements LE may be disposed between the pixel electrodes PE1, PE2, and PE3, or may be partially disposed over any one pixel electrode, or may not be disposed on any pixel electrode.

For example, the second via layer VIA2 may be disposed on the substrate 110 on which the common electrode CE is disposed. The second via layer VIA2 may be disposed on the common electrode CE, and may not cover the light emitting elements LE. In an embodiment, the second via layer VIA2 may be disposed (e.g., directly disposed) on the common electrode CE and may be in contact with the side surfaces of the light emitting elements LE. However, the second via layer VIA2 may not be disposed on the top surfaces of the light emitting elements LE.

In an embodiment, the second via layer VIA2 may flatten the stepped portion formed by the light emitting element LE for a subsequent process. The height of the second via layer VIA2 and the heights of the light emitting elements LE may be the same as each other. For example, the height of the top surface of the second via layer VIA2 measured from each of the pixel electrodes PE1, PE2, and PE3 may be aligned with the heights of the top surfaces of the light emitting elements LE (e.g., the height of the top surface of the third semiconductor layer). However, embodiments are not limited thereto, and the height of the top surface of the second via layer VIA2 may be lower than the heights of the top surfaces of the light emitting elements LE.

The first via layer VIA1 and the second via layer VIA2 may include the same material as each other described above. For example, the second via layer VIA2 may include acrylic resin, epoxy resin, phenolic resin, polyamide resin, polyimide resin, unsaturated polyester resin, polyphenylene resin, polyphenylenesulfide resin, benzocyclobutene (BCB), or the like.

The light emitting element unit LEP may further include a first capping layer CAP1 covering the common electrode CE. The first capping layer CAP1 may be disposed (e.g., directly disposed) on the second via layer VIA2 and the common electrode CE. The first capping layer CAP1 may function to cover the elements disposed thereunder, e.g., the light emitting elements LE and the common electrode CE, to protect them from moisture or foreign substances.

The first capping layer CAP1 may include an inorganic material. For example, the first capping layer CAP1 may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. For example, although it is illustrated in the drawing that the first capping layer CAP1 is formed as a single layer, embodiments are not limited thereto. For example, the first capping layer CAP1 may be formed as a multilayer in which inorganic layers, each of which includes at least one of the aforementioned example materials that are included in the first capping layer CAP1, are alternately stacked. The thickness of the first capping layer CAP1 may range from about 0.05 μm to about 2 μm, but embodiments are not limited thereto.

Referring to FIG. 6, the wavelength controller 200 may be disposed on the light emitting element unit LEP. The wavelength controller 200 may include a wavelength conversion layer QDL, a first reflective layer RFL1, a second reflective layer RFL2, a definition wall PWL including a first definition wall PW1 and a second definition wall PW2, and a cover layer TRL.

The definition wall PWL may be disposed on the first capping layer CAP1, and may define the emission areas EA1, EA2, and EA3. The definition wall PWL may extend in the first direction DR1 and the second direction DR2, and may be formed in a grid pattern in the entire display area DPA. Further, the definition wall PWL may not overlap the emission areas EA1, EA2, and EA3, and may overlap the non-emission area NEA.

The definition wall PWL may function to provide a space for forming the wavelength conversion layer QDL. For example, the definition wall PWL may include the first definition wall PW1 and the second definition wall PW2 disposed on the first definition wall PW1. In order to provide a space for forming the wavelength conversion layer QDL, the definition wall PWL may have a two-layer structure including the first definition wall PW1 and the second definition wall PW2 to have a large thickness. For example, the thickness of the first definition wall PW1 and the thickness of the second definition wall PW2 may be within a range of about 1 μm to about 10 μm. The first definition wall PW1 and the second definition wall PW2 may include an organic insulating material to have a large thickness. The organic insulating material may include, for example, epoxy resin, acrylic resin, cardo resin or imide resin.

In an embodiment, the first definition wall PW1 and the second definition wall PW2 may block transmission of light in the non-emission area NEA. The first definition wall PW1 and the second definition wall PW2 may further include a light blocking material, and may include a dye or pigment having a light blocking property. For example, the first definition wall PW1 and the second definition wall PW2 may be a black matrix. External light incident from the outside of the display device 10 may cause a problem that color reproducibility of the wavelength controller 200 is distorted. In accordance with an embodiment, at least a portion of the external light may be absorbed by the light blocking member BK by disposing the definition wall PWL including the light blocking material in the wavelength controller 200. Accordingly, color distortion caused by the reflection of the external light may be reduced. Further, the definition wall PWL including the light blocking material may prevent light infiltration and color mixture between adjacent emission areas, which leads to further improvement of color reproducibility.

The first reflective layer RFL1 may be disposed between the definition wall PWL and the first capping layer CAP1. The first reflective layer RFL1 may not overlap the emission areas EA1, EA2, and EA3, and may overlap the non-emission area NEA. The first reflective layer RFL1 may extend in the first direction DR1 and the second direction DR2, and may be formed in a grid pattern in the entire display area DPA. The first reflective layer RFL1 may overlap (e.g., entirely overlap) the definition wall PWL.

The first reflective layer RFL1 may reflect light emitted from the light emitting elements LE upward (e.g., in the third direction DR3). The first reflective layer RFL1 may include a metal material having conductivity and high light reflectivity. The first reflective layer RFL1 may include, e.g., aluminum (Al) or silver (Ag), or an alloy thereof.

The second reflective layer RFL2 may be disposed on the definition wall PWL. The second reflective layer RFL2 may not overlap the emission areas EA1, EA2, and EA3 and may overlap the non-emission area NEA. The second reflective layer RFL2 may extend in the first direction DR1 and the second direction DR2, similar to the first reflective layer RFL1, and may be formed in a grid pattern in the entire display area DPA. The second reflective layer RFL2 may overlap (e.g., entirely overlap) the definition wall PWL and the first reflective layer RFL1. The second reflective layer RFL2 may cover both the first definition wall PW1 and the second definition wall PW2 of the definition wall PWL1.

Similar to the first reflective layer RFL1, the second reflective layer RFL2 may reflect light emitted from the light emitting elements LE upward (e.g., in the third direction DR3). The first reflective layer RFL1 and the second reflective layer RFL2 may include the same material as each other.

The cover layer TRL may be disposed on the second reflective layer RFL2. The cover layer TRL may overlap a portion of the emission areas EA1, EA2, and EA3 and the non-emission area NEA. The cover layer TRL may extend in the first direction DR1 and the second direction DR2, and may be formed in a grid pattern in the entire display area DPA.

The cover layer TRL may cover the definition wall PWL and the second reflective layer RFL2, and may function as a mask for etching the second reflective layer RFL2. Accordingly, the lateral side of the cover layer TRL and the lateral side of the second reflective layer RFL2 may be aligned with each other. Further, the cover layer TRL may include a light transmitting organic material so that light reflected from the second reflective layer RFL2 may be emitted upward. For example, the cover layer TRL may include epoxy resin, acrylic resin, cardo resin, imide resin, or the like.

For example, the wavelength conversion layer QDL may be disposed on each of the emission areas EA1, EA2, and EA3. The wavelength conversion layer QDL may emit light by converting or shifting the peak wavelength of incident light to another specific peak wavelength. The wavelength conversion layer QDL may convert the first light that is blue light emitted from the light emitting element LE into the second light that is red light or into the third light that is green light, or may transmit the first light that is blue light without conversion.

The wavelength conversion layer QDL may be disposed in each of the emission areas EA1, EA2, and EA3 partitioned (or defined) by the definition wall PWL, and may be spaced apart from each other. For example, the wavelength conversion layer QDL may be formed of an island pattern in a shape of dots spaced apart from each other. The wavelength conversion layer QDL may overlap each of the first emission area EA1, the second emission area EA2, and the third emission area EA3. In an embodiment, each of the wavelength conversion layers QDL may overlap (e.g., completely overlap) the first emission area EA1, the second emission area EA2, and the third emission area EA3.

The wavelength conversion layer QDL may include a first wavelength conversion pattern member WCL1 overlapping the first emission area EA1, a second wavelength conversion pattern member WCL2 overlapping the second emission area EA2, and a light transmission pattern member TPL overlapping the third emission area EA3.

The first wavelength conversion pattern member WCL1 may overlap the first emission area EA1. The first wavelength conversion pattern member WCL1 may emit light by converting or shifting the peak wavelength of incident light to another specific peak wavelength. In an embodiment, the first wavelength conversion pattern member WCL1 may convert the first light that is blue light emitted from the light emitting element LE of the first emission area EA1 into the second light that is red light having a single peak wavelength in the range of about 610 nm to about 650 nm and emit the red light.

The first wavelength conversion pattern member WCL1 may include a first base resin BRS1, a first wavelength conversion particle WCP1, and a scatterer SCP. The first base resin BRS1 may include a transparent organic material. For example, the first base resin BRS1 may include epoxy resin, acrylic resin, cardo resin, or imide resin.

The first wavelength conversion particle WCP1 may convert the first light incident from the light emitting element LE into second light. For example, the first wavelength conversion particle WCP1 may convert light in a blue wavelength band into light in a red wavelength band. The first wavelength conversion particle WCP1 may be a quantum dot (QD), a quantum rod, a fluorescent material, or a phosphorescent material. For example, a quantum dot may be a certain material that emits light of a specific color in case that an electron transitions from a conduction band to a valence band.

The quantum dot may be a semiconductor nanocrystal material. The quantum dot may have a specific band gap according to its composition and size. Thus, the quantum dot may absorb light, and may emit light having an intrinsic wavelength. Examples of semiconductor nanocrystal of quantum dots may include group IV nanocrystal, group II-VI compound nanocrystal, group III-V compound nanocrystal, group IV-VI nanocrystal, a combination thereof, or the like.

The group II-VI compound may be selected from the group of binary compounds, ternary compounds, and quaternary compounds, wherein the binary compounds may be selected from the group of CdSe, CdTe, ZnS, ZnSe, ZnTe, ZnO, HgS, HgSe, HgTe, MgSe, MgS and mixtures thereof, the ternary compounds may be selected from the group of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof, and the quaternary compounds may be selected from the group of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The group III-V compound may be selected from the group of binary compounds, ternary compounds, and quaternary compounds, wherein the binary compounds may be selected from the group of GaN, GaP, GaAs, GaSb, AlN, AlP, AlAs, AlSb, InN, InP, InAs, InSb and mixtures thereof, the ternary compounds may be selected from the group of GaNP, GaNAs, GaNSb, GaPAs, GaPSb, AlNP, AINAs, AlNSb, AlPAs, AlPSb, InGaP, InNP, InAlP, InNAs, InNSb, InPAs, InPSb, GaAlNP and mixtures thereof, and the quaternary compounds may be selected from the group of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof.

The group IV-VI compound may be selected from the group of binary compounds, ternary compounds, and quaternary compounds, wherein the binary compounds may be selected from the group of SnS, SnSe, SnTe, PbS, PbSe, PbTe and mixtures thereof, the ternary compounds may be selected from the group of SnSeS, SnSeTe, SnSTe, PbSeS, PbSeTe, PbSTe, SnPbS, SnPbSe, SnPbTe and mixtures thereof, and the quaternary compounds may be selected from the group of SnPbSSe, SnPbSeTe, SnPbSTe and mixtures thereof. The group IV element may be selected from the group of Si, Ge and mixtures thereof. The group IV compound may be a binary compound selected from the group of SiC, SiGe and mixtures thereof.

For example, the binary compound, the tertiary compound or the quaternary compound may exist in particles at a uniform concentration, or may exist in the same particle divided into states where concentration distributions are partially different. Further, the particles may have a core/shell structure in which one quantum dot surrounds another quantum dot. An interface between the core and the shell may have a concentration gradient in which the concentration of elements present in the shell decreases toward the center portion.

In an embodiment, the quantum dot may have a core-shell structure including a core including the nanocrystal described above and a shell surrounding the core. The shell of the quantum dot may function as a protective layer for maintaining semiconductor characteristics by preventing chemical denaturation of the core and/or as a charging layer for giving electrophoretic characteristics to the quantum dot. The shell may be a single layer or a multilayer. Examples of the shell of the quantum dot may include a metal or non-metal oxide, a semiconductor compound, and a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a tertiary compound such as MgAl₂O₄, CoFe₂O₄, NiFe₂O₄ and CoMn₂O₄, but embodiments are not limited thereto.

For example, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb or the like, but embodiments are not limited thereto.

The scatterer SCP may scatter light of the light emitting element LE in random directions. The scatterer SCP may have a refractive index different from that of the first base resin BRS1 and may form an optical interface with the first base resin BRS1. For example, the scatterer SCP may be light scattering particles. The scatterer SCP is not limited as long as it is a material capable of scattering at least a portion of the transmitted light, but may be, for example, metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include acrylic resin and urethane resin, and the like. The scatterer SCP may scatter light in random directions regardless of the incidence direction of the incident light without substantially converting the wavelength of the light.

The second wavelength conversion pattern member WCL2 may overlap the second emission area EA2. The second wavelength conversion pattern member WCL2 may emit light by converting or shifting the peak wavelength of incident light to another specific peak wavelength. In an embodiment, the second wavelength conversion pattern member WCL2 may convert the first light that is blue light emitted from the light emitting element LE of the second emission area EA2 into the third light that is green light having a peak wavelength in the range of about 510 nm to about 550 nm and emit the green light.

The second wavelength conversion pattern member WCL2 may include a second base resin BRS2, and a second wavelength conversion particle WCP2 and a scatterer SCP dispersed in the second base resin BRS2.

The second base resin BRS2 may be made of a material having a high light transmittance, and may be made of the same material as that of the first base resin BRS1, or may include at least one of the materials such as the constituent materials thereof.

The second wavelength conversion particle WCP2 may convert or shift the peak wavelength of incident light to another specific peak wavelength. In an embodiment, the second wavelength conversion particle WCP2 may convert the first light that is blue light provided from the light emitting element LE into the third light that is green light having a peak wavelength in the range of about 510 nm to about 550 nm and emit the green light. Examples of the second wavelength conversion particle WCP2 may include a quantum dot, a quantum rod, a phosphor, and the like. A more detailed description of the second wavelength conversion particle WCP2 is substantially the same as or similar to the description of the first wavelength conversion particle WCP1, and thus will be omitted for descriptive convenience.

The light transmission pattern member TPL may overlap the third emission area EA3. The light transmission pattern member TPL may transmit incident light. The light transmission pattern member TPL may transmit the first light that is blue light emitted from the light emitting element LE disposed in the third emission area EA3 without conversion. The light transmission pattern member TPL may include a third base resin BRS3 and the scatterer SCP dispersed in the third base resin BRS3. Since the third base resin BRS3 is substantially the same as or similar to the above-described first base resin BRS1, a description thereof will be omitted for descriptive convenience.

The first light, the second light, and the third light emitted from the above-described wavelength controller 200 may pass through the color filter layer CFL to be described below to perform a full color display.

The wavelength controller 200 may further include a second capping layer CAP2 disposed on the cover layer TRL and the wavelength conversion layer QDL. The second capping layer CAP2 may function to cover the wavelength conversion layer QDL disposed thereunder and protect them from moisture or foreign substances. The second capping layer CAP2 may include an inorganic material, and may include a material substantially the same as or similar to that of the above-described first capping layer CAP1.

For example, the color filter layer CFL may be disposed on the wavelength controller 200. The color filter layer CFL may include a first overcoat layer OC1, a first color filter CF1, a second color filter CF2, a third color filter CF3, and a second overcoat layer OC2.

The first overcoat layer OC1 may be disposed on the wavelength controller 200. The first overcoat layer OC1 may be disposed (e.g., directly disposed) on the second capping layer CAP2 of the wavelength controller 200. The first overcoat layer OC1 may be disposed (e.g., entirely disposed) in the display area DPA, and may have a flat surface. The first overcoat layer OC1 may flatten the stepped portion formed thereunder by the wavelength controller 200 to facilitate the formation of the color filter layer CFL.

The first overcoat layer OC1 may include a light transmitting organic material. For example, the first overcoat layer OC1 may include epoxy resin, acrylic resin, cardo resin, imide resin, or the like.

The first color filter CF1, the second color filter CF2, and the third color filter CF3 may be disposed on the first overcoat layer OC1. The first color filter CF1 may be disposed in the first emission area EA1, the second color filter CF2 may be disposed in the second emission area EA2, and the third color filter CF3 may be disposed in the third emission area EA3.

The first color filter CF1, the second color filter CF2, and the third color filter CF3 may include a colorant such as a dye or pigment that absorbs a wavelength other than a corresponding color wavelength. The first color filter CF1 may selectively transmit the second light (e.g., red light), and may block or absorb the first light (e.g., blue light) and the third light (e.g., green light). The second color filter CF2 may selectively transmit the third light (e.g., green light), and may block or absorb the first light (e.g., blue light) and the second light (e.g., red light). The third color filter CF3 may selectively transmit the first light (e.g., blue light), and block or absorb the second light (e.g., red light) and the third light (e.g., green light). For example, the first color filter CF1 may be a red color filter, the second color filter CF2 may be a green color filter, and the third color filter CF3 may be a blue color filter.

In an embodiment, the light incident on the first color filter CF1 may be the second light converted by the first wavelength conversion pattern member WCL1, the light incident on the second color filter CF2 may be the third light converted by the second wavelength conversion pattern member WCL2, and the light incident on the third color filter CF3 may be the first light that has passed through the light transmission pattern member TPL. As a result, the second light transmitted through the first color filter CF1, the third light transmitted through the second color filter CF2, and the first light transmitted through the third color filter CF3 may be emitted upwards from the substrate 110 to perform a full color display.

The first color filter CF1, the second color filter CF2, and the third color filter CF3 may absorb a portion of the light incident from the outside of the display device 10 to reduce the reflected light of the external light. Accordingly, the first color filter CF1, the second color filter CF2, and the third color filter CF3 may prevent color distortion caused by the reflection of the external light.

As illustrated in FIG. 10, the planar area of each of the first color filter CF1, the second color filter CF2, and the third color filter CF3 may be greater than the planar area of each of the emission areas EA1, EA2, and EA3. For example, the first color filter CF1 may have a larger planar area than the first emission area EA1. The second color filter CF2 may have a larger planar area than the second emission area EA2. The third color filter CF3 may have a larger planar area than the third emission area EA3. However, embodiments are not limited thereto, and the planar area of each of the first color filter CF1, the second color filter CF2, and the third color filter CF3 may be the same as the planar area of each of the emission areas EA1, EA2, and EA3.

The second overcoat layer OC2 may be disposed on the color filter layer CFL. The second overcoat layer OC2 may be disposed (e.g., directly disposed) on the color filter layer CFL. The second overcoat layer OC2 may be disposed (e.g., entirely disposed) in the display area DPA, and may have a flat surface. The second overcoat layer OC2 may flatten the stepped portion formed by the lower color filter layer CFL disposed thereunder. The second overcoat layer OC2 may include a light transmitting organic material, and may be substantially the same as or similar to the above-described first overcoat layer OC1.

As described above, in the display device 10 according to an embodiment, the common electrode CE may be in contact with the side surface of the second semiconductor layer SEM2 of each light emitting element LE. Thus, the current flowing through the light emitting element LE may be induced to flow between the common electrode CE having a low resistance and the second semiconductor layer SEM2, thereby improving the luminous efficiency of the light emitting element LE.

For example, in FIGS. 9A and 9B, the light emitting elements LE may be arranged to be aligned with arbitrary parallel lines extending in a direction. For example, they may be arranged in an inclined matrix, and rows and columns may be arranged by the same interval (or constant distance). Further, the light emitting elements LE may have the same arrangement on each of the pixel electrodes PE1, PE2, and PE3. However, embodiments are not limited thereto, and the arrangement of the light emitting elements LE disposed on each of the pixel electrodes PE1, PE2, and PE3 may be irregular.

Further, FIG. 6 illustrates that a pixel includes three emission areas including the first emission area EA1 emitting the second light, the second emission area EA2 emitting the third light, and the third emission area EA3 emitting the first light.

Referring to FIGS. 11 to 13, in another example, there are two third emission area EA3 emitting the first light, so that a pixel may include four emission areas EA1, EA2, and EA3.

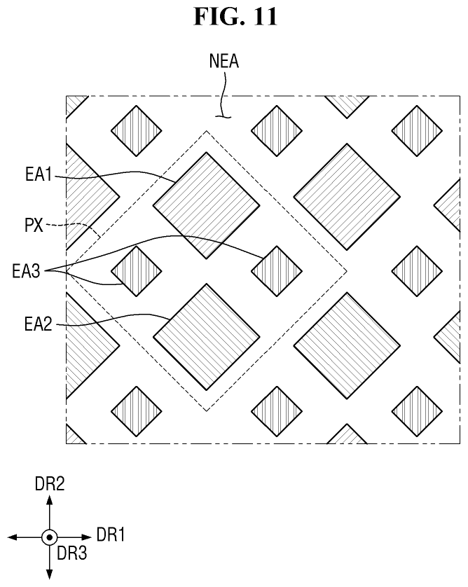

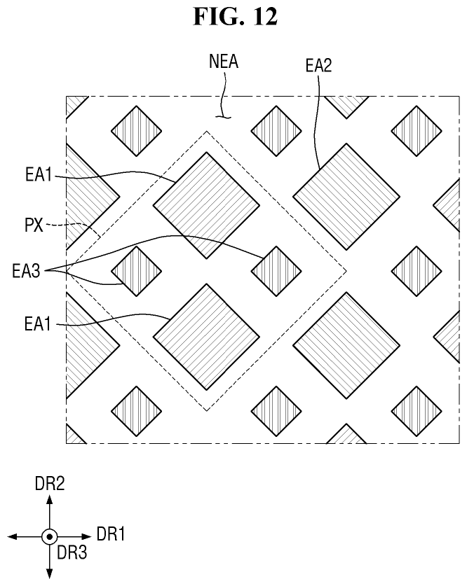

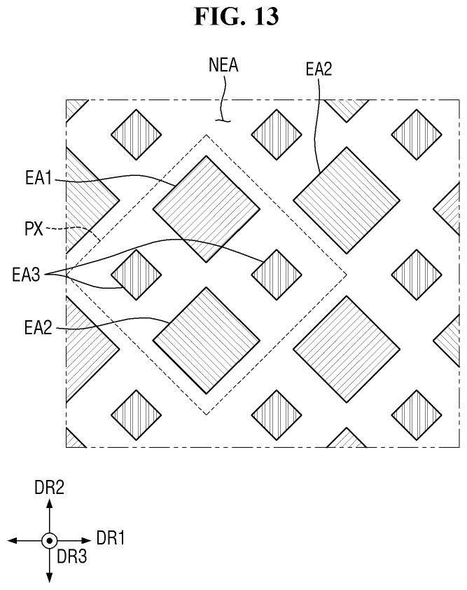

In an embodiment, each of the emission areas EA1, EA2, and EA3 may have a Pentile™ structure. As illustrated in FIG. 11, the first emission areas EA1 may be arranged in a first row along the first direction DR1, the second emission areas EA2 may be arranged in a second row along the first direction, and the first row and the second row may be alternately and repeatedly arranged along the second direction DR2. Further, as shown in FIG. 12, the first emission areas EA1 may be arranged in a first column along the second direction DR2, the second emission areas EA2 may be arranged in a second column along the second direction DR2, and the first column and the second column may be alternately and repeatedly arranged along the first direction DR1. Further, as illustrated in FIG. 13, the first emission area EA1 and the second emission area EA2 may be alternately and repeatedly arranged in the first direction DR1 and the second direction DR2.

In another example, the area of the first emission area EA1, the area of the second emission area EA2, and the area of the third emission areas EA3 may be substantially the same, but embodiments are not limited thereto. For example, as shown in FIGS. 11 to 13, the area of the first emission area EA1 and the area of the second emission area EA2 may be the same, and the area of the third emission areas EA3 may be different from the area of the first emission area EA1 and the area of the second emission area EA2. Further, the area of the first emission area EA1 may be greater than the area of the second emission area EA2, or the area of the first emission area EA1 may be smaller than the area of the second emission area EA2.

Further, the distance between the first emission area EA1 and the second emission area EA2 adjacent to each other, the distance between the second emission area EA2 and the third emission areas EA3 adjacent to each other, and the distance between the first emission area EA1 and the third emission areas EA3 adjacent to each other may be substantially the same, but embodiments are not limited thereto. For example, the distance between the first emission area EA1 and the second emission area EA2 adjacent to each other and the distance between the second emission area EA2 and the third emission areas EA3 adjacent to each other may be different from each other, and the distance between the first emission area EA1 and the third emission areas EA3 adjacent to each other and the distance between the second emission area EA2 and the third emission areas EA3 adjacent to each other may be different from each other.

Further, the first emission area EA1 may emit the second light, the second emission area EA2 may emit the third light, and the third emission area EA3 may emit the first light, but embodiments are not limited thereto. For example, the first emission area EA1 may emit the first light, the second emission area EA2 may emit the second light, and the third emission areas EA3 may emit the third light. In another example, the first emission area EA1 may emit the third light, the second emission area EA2 may emit the first light, and the third emission areas EA3 may emit the second light. In another example, the first emission area EA1 may emit the third light, the second emission area EA2 may emit the second light, and the third emission areas EA3 may emit the first light.

Further, the first emission area EA1, the second emission area EA2, and the third emission areas EA3 may have a rectangular planar shape, but embodiments are not limited thereto. For example, the first emission area EA1, the second emission area EA2, and the third emission areas EA3 may have a polygonal shape, such as a triangular shape, a pentagonal shape, a hexagonal shape, and an octagonal shape, a circular shape, an elliptical shape, or an atypical shape.

Hereinafter, the display device 10 according to an embodiment will be described with reference to other drawings.

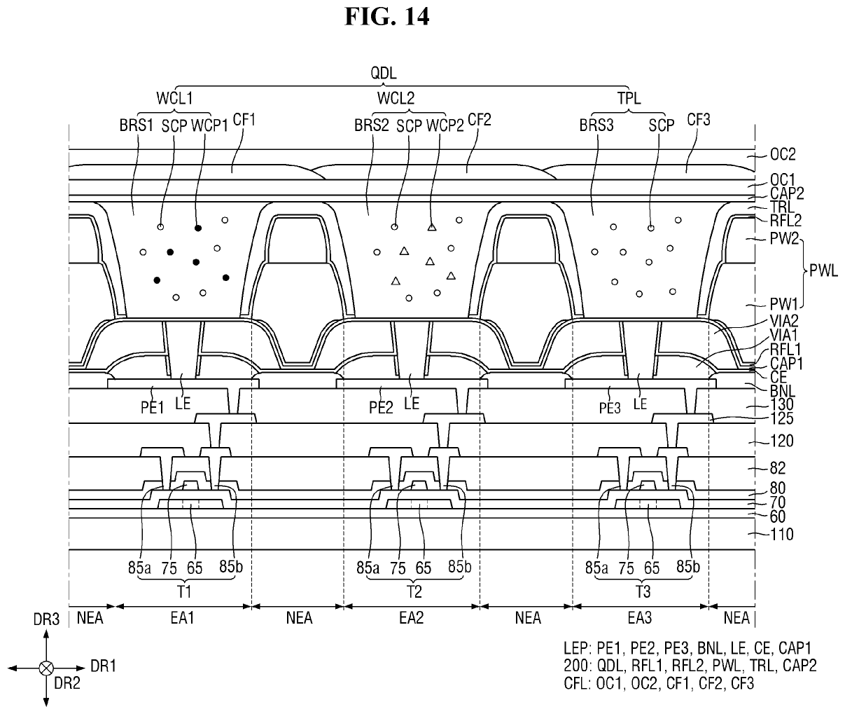

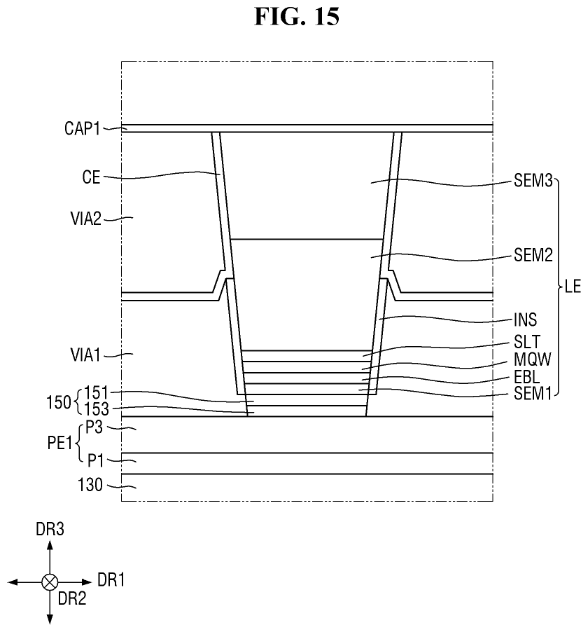

FIG. 14 is a schematic cross-sectional view schematically illustrating a display device according to an embodiment. FIG. 15 is a schematic cross-sectional view illustrating a pixel electrode and a light emitting element according to an embodiment.

Referring to FIGS. 14 and 15, the embodiment is different from the above-described embodiment of FIGS. 6 to 10 in that the common electrode CE is in contact with only the side surface of the light emitting element LE. Hereinafter, descriptions of the same components will be simplified or omitted, and differences will be described in detail for descriptive convenience.

The common electrode CE may be disposed on the light emitting element LE and the first via layer VIA1. The common electrode CE may be in contact with (e.g., in direct contact with) the side surface of the second semiconductor layer SEM2 and the side surface of the third semiconductor layer SEM3 of the light emitting element LE. For example, the common electrode CE may be in contact with (e.g., in direct contact with) the outer circumferential surface of the second semiconductor layer SEM2 of the light emitting element LE and may be in contact with (e.g., in direct contact with) the outer circumferential surface of the third semiconductor layer SEM3 thereof.

The common electrode CE may be spaced apart from the top surface of the light emitting element LE, i.e. the top surface of the third semiconductor layer SEM3. The common electrode CE may not be disposed on the top surface of the third semiconductor layer SEM3 and may expose the top surface of the third semiconductor layer SEM3. The uppermost surface of the common electrode CE disposed on the side surface of the third semiconductor layer SEM3 and the top surface of the third semiconductor layer SEM3 may be aligned with each other.

The contact resistance between the common electrode CE and the third semiconductor layer SEM3 may be considerably higher than the contact resistance between the common electrode CE and the second semiconductor layer SEM2. In an embodiment, the common electrode CE may expose the top surface of the third semiconductor layer SEM3, so that the area in which the common electrode CE may be in contact with the third semiconductor layer SEM3 may be reduced. Accordingly, the common electrode CE may be in contact with the side surface of the second semiconductor layer SEM2. Thus, the current flowing through the light emitting element LE may be induced to flow between the common electrode CE having a low resistance and the second semiconductor layer SEM2, thereby improving the luminous efficiency of the light emitting element LE.

For example, the second via layer VIA2 may be disposed on the common electrode CE, and the first capping layer CAP1 may be disposed on the second via layer VIA2, the common electrode CE, and the light emitting element LE. The top surface of the second via layer VIA2, the top surface of the common electrode CE, and the top surface of the light emitting element LE may be aligned with each other. For example, the top surface of the second via layer VIA2, the top surface of the common electrode CE, and the top surface of the light emitting element LE may be arranged side by side with the substrate 110, and may be flat. The first capping layer CAP1 may be in contact with (e.g., in direct contact with) the top surface of the second via layer VIA2, the top surface of the common electrode CE, and the top surface of the third semiconductor layer SEM3 of the light emitting element LE.

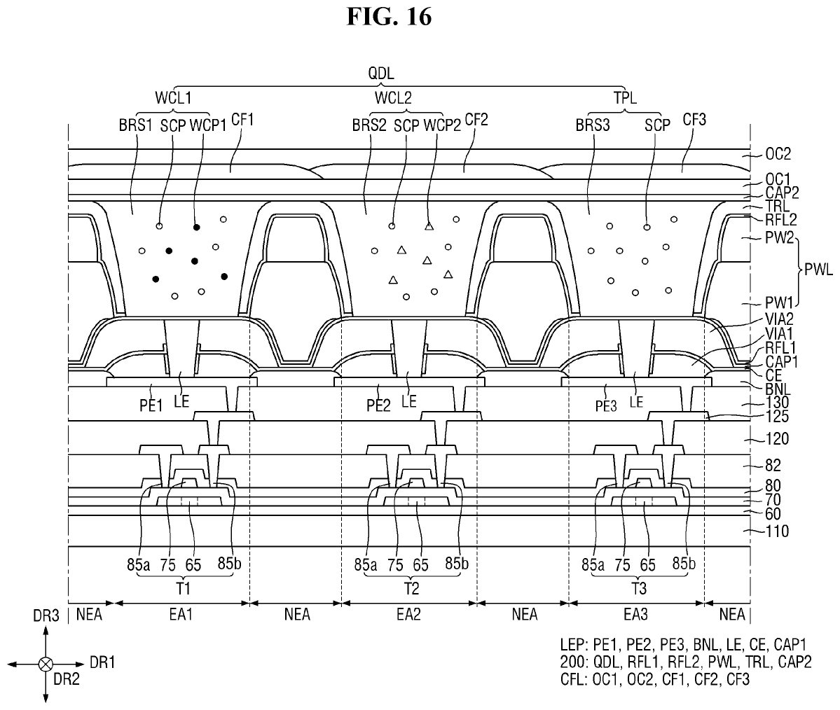

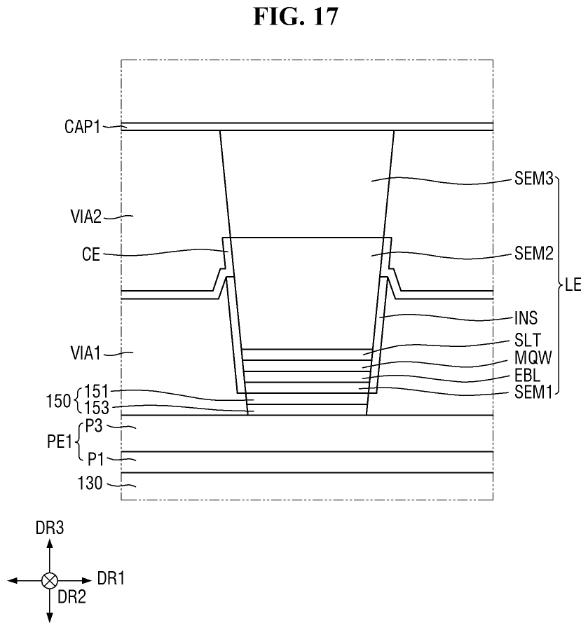

FIG. 16 is a schematic cross-sectional view schematically illustrating a display device according to an embodiment. FIG. 17 is a schematic cross-sectional view illustrating a pixel electrode and a light emitting element according to an embodiment.

Referring to FIGS. 16 and 17, the embodiment is different from the embodiment of FIGS. 6 to 17 in that the common electrode CE is in contact with only the side surface of the second semiconductor layer SEM2 of the light emitting element LE. Hereinafter, descriptions of the same components will be simplified or omitted, and differences will be described in detail for descriptive convenience.

The common electrode CE may be disposed on the light emitting element LE and the first via layer VIA1. The common electrode CE may be in contact with (e.g., in direct contact with) the side surface of the second semiconductor layer SEM2 of the light emitting element LE. For example, the common electrode CE may be in contact with (e.g., in direct contact with) the outer circumferential surface of the second semiconductor layer SEM2 of the light emitting element LE.

The common electrode CE may be spaced apart from the top surface and a portion of the side surface of the light emitting element LE, e.g., the top and side surfaces of the third semiconductor layer SEM3. The common electrode CE may not be disposed on the top and side surfaces of the third semiconductor layer SEM3, and may expose the top and side surfaces of the third semiconductor layer SEM3. Further, the uppermost surface of the common electrode CE disposed on the side surface of the second semiconductor layer SEM2 and the bottom surface of the third semiconductor layer SEM3 may be aligned with each other. The uppermost surface of the common electrode CE disposed on the side surface of the second semiconductor layer SEM2 and the top surface of the second semiconductor layer SEM2 may be aligned with each other.

The contact resistance between the common electrode CE and the third semiconductor layer SEM3 may be considerably higher than the contact resistance between the common electrode CE and the second semiconductor layer SEM2. In an embodiment, the common electrode CE may expose the top and side surfaces of the third semiconductor layer SEM3 so as not to be in contact with the third semiconductor layer SEM3. Accordingly, the common electrode CE may be in contact with only the side surface of the second semiconductor layer SEM2, so that the current flowing through the light emitting element LE may flow between the common electrode CE having a low resistance and the second semiconductor layer SEM2, thereby improving the luminous efficiency of the light emitting element LE.

For example, the second via layer VIA2 may be disposed on the common electrode CE. The second via layer VIA2 may be in contact with (e.g., in direct contact with) the side surface of the third semiconductor layer SEM3 of the light emitting element LE. The first capping layer CAP1 may be disposed on the second via layer VIA2, the common electrode CE, and the light emitting element LE. The top surface of the second via layer VIA2, the top surface of the common electrode CE, and the top surface of the light emitting element LE may be aligned with each other. For example, the top surface of the second via layer VIA2, the top surface of the common electrode CE, and the top surface of the light emitting element LE may be arranged side by side with the substrate 110, may be coplanar with each other, and may be flat. The first capping layer CAP1 may be in contact with (e.g., in direct contact with) the top surface of the second via layer VIA2, the top surface of the common electrode CE, and the top surface of the third semiconductor layer SEM3 of the light emitting element LE.

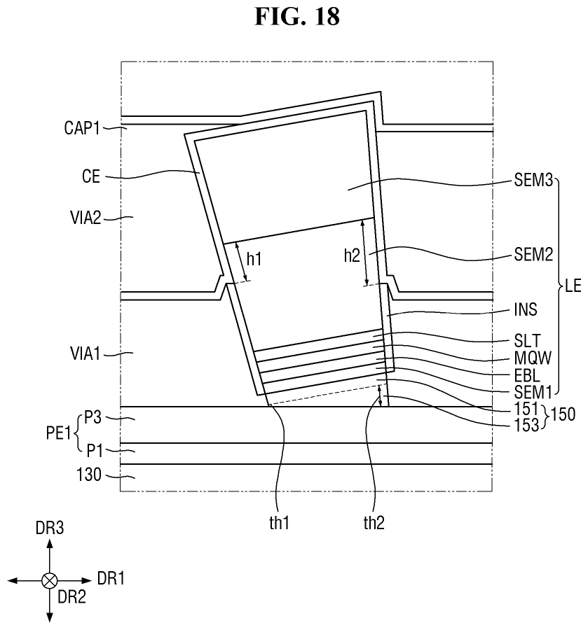

FIG. 18 is a schematic cross-sectional view illustrating a pixel electrode and a light emitting element according to an embodiment.

Referring to FIG. 18, the embodiment is different from the above-described embodiment of FIGS. 6 to 17 in that the light emitting element LE is disposed on the first pixel electrode PE1 in an inclined state. Hereinafter, descriptions of the same components will be simplified or omitted, and differences will be described in detail for descriptive convenience.

The light emitting element LE may be disposed on the first pixel electrode PE1. The light emitting element LE may be adhered to the first pixel electrode PE1 by a bonding process described below. For example, the connection layer 153 of the connection electrode 150 of the light emitting element LE may be melted by high heat and adhered on the first pixel electrode PE1. In case that the connection layer 153 is irregularly melted in the bonding process, the connection layer 153 may be non-uniformly bonded with a non-uniform thickness. For example, a thickness (e.g., th1 in FIG. 18) of a portion of the connection layer 153 may be different from a thickness (e.g., th2 in FIG. 18) of another portion of the connection layer 153. Accordingly, the light emitting element LE adhered to the first pixel electrode PE1 by the connection electrode 150 may be inclined with respect to the top surface of the first pixel electrode PE1.

The first via layer VIA1 may be disposed on the first pixel electrode PE1. The first via layer VIA1 may be in contact with (e.g., in direct contact with) the side surface, e.g., the outer circumferential surface of the light emitting element LE. The insulating layer INS of the light emitting element LE may surround the entire outer circumferential surface of the light emitting element LE and etched by using the first via layer VIA1 as a mask, and thus may have a height substantially the same as or similar to the height of the top surface of the first via layer VIA1. For example, the height of the first via layer VIA1 may be the same as the height of the insulating layer INS. In case that the light emitting element LE is inclined in an inclined direction (or a diagonal direction), the lengths (e.g., h1 and/or h2 in FIG. 18) of the side surfaces (e.g., left and right side surfaces) of the second semiconductor layer SEM2 exposed by the insulating layer INS may be different according to areas. For example, the length h1 of the side surface (e.g., left side surface) of the second semiconductor layer SEM2 exposed by the insulating layer INS on a side of the light emitting element LE may be smaller than the length h2 of the side surface (e.g., right side surface) of the second semiconductor layer SEM2 exposed by the insulating layer INS on another side of the light emitting element LE. Further, the lengths (e.g., h1 and/or h2 in FIG. 18) of the side surfaces of the second semiconductor layer SEM2 exposed by the insulating layer INS may vary from a side toward another side of the light emitting element LE. For example, the lengths (e.g., h1 and/or h2 in FIG. 18) of the side surfaces of the second semiconductor layer SEM2 exposed by the insulating layer INS may gradually increase or decrease from a side toward another side of the light emitting element LE.

The common electrode CE may be disposed on the first via layer VIA1 and the light emitting element LE. The common electrode CE may cover the inclined light emitting element LE, and may be in contact with the top and side surfaces of the light emitting element LE. For example, the common electrode CE may be in contact with the side surface of the second semiconductor layer SEM2, and the top and side surfaces of the third semiconductor layer SEM3 of the light emitting element LE. In case that the light emitting element LE is inclined, the total area of the side surface of the second semiconductor layer SEM2 exposed by the insulating layer INS may not change. In case that the length h1 of the side surface (e.g., left side surface) of the second semiconductor layer SEM2 exposed by the insulating layer INS decreases, the length h2 of the another side (e.g., right side surface) surface may increase, so that the total area of the side surface of the second semiconductor layer SEM2 exposed by the insulating layer INS may not change.

In an embodiment, the common electrode CE may be in contact with only the side surface of the second semiconductor layer SEM2. Thus, although the light emitting element LE is formed in an inclined state, the contact area between the common electrode CE and the second semiconductor layer SEM2 may be maintained, thereby improving the luminous efficiency.

For example, the second via layer VIA2 may be disposed on the common electrode CE, and the first capping layer CAP1 may be disposed on the second via layer VIA2 and the common electrode CE. The second via layer VIA2 may cover a portion of the top surface of the light emitting element LE, and may expose another part thereof. For example, a portion of the top surface of the third semiconductor layer SEM3 of the light emitting element LE may be covered by the second via layer VIA2 to overlap the second via layer VIA2. Further, another portion of the top surface of the third semiconductor layer SEM3 of the light emitting element LE may protrude more upward than the second via layer VIA2 and may not overlap the second via layer VIA2.

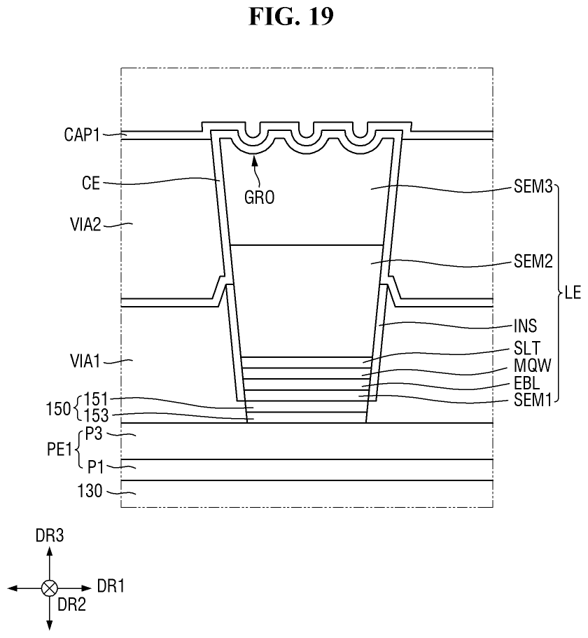

FIG. 19 is a schematic cross-sectional view illustrating a pixel electrode and a light emitting element according to an embodiment.

Referring to FIG. 19, the embodiment is different from the above-described embodiment of FIGS. 6 to 18 in that grooves GRO are disposed on the top surface of the third semiconductor layer SEM3 of the light emitting element LE. Hereinafter, descriptions of the same components will be simplified or omitted, and differences will be described in detail for descriptive convenience.

The third semiconductor layer SEM3 of the light emitting element LE may include the grooves GRO. The grooves GRO may be disposed on the top surface of the third semiconductor layer SEM3. The grooves GRO may be formed by a process of etching the top surface of the third semiconductor layer SEM3 during the manufacturing process of the light emitting element LE, which will be described below. The grooves GRO may have a shape in which the top surface of the third semiconductor layer SEM3 is recessed toward the first pixel electrode PE1. The grooves GRO may reflect and diffuse light emitted from the active layer MQW of the light emitting element LE, thereby improving the luminous efficiency.

The grooves GRO may have a hemispherical shape, but the shape thereof is not limited thereto, and the grooves GRO may be formed in other shapes as long as they have a curvature. Although FIG. 19 illustrates that the grooves GRO have the same size and are spaced apart from each other by the same interval (or constant distance), embodiments are not limited thereto, and the sizes of the grooves GRO and the intervals therebetween may be different from each other, or may be partially the same and partially different.

The etching process of forming the grooves GRO in the third semiconductor layer SEM3 may damage the top surface of the third semiconductor layer SEM3. In case that the common electrode CE is in contact with only the third semiconductor layer SEM3, the contact resistance between the common electrode CE and the third semiconductor layer SEM3 may be further increased. In an embodiment, in case that the grooves GRO are formed in the top surface of the third semiconductor layer SEM3, the common electrode CE may be in contact with the side surface of the second semiconductor layer SEM2. Thus, the current flowing through the light emitting element LE may be induced to flow between the common electrode CE having a low resistance and the second semiconductor layer SEM2, thereby improving the luminous efficiency of the light emitting element LE.

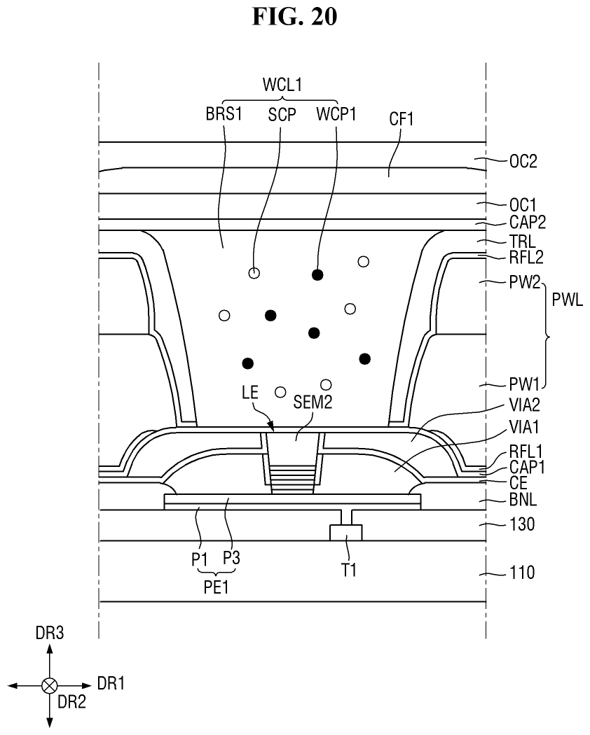

FIG. 20 is a schematic cross-sectional view illustrating a pixel electrode and a light emitting element according to an embodiment.

Referring to FIG. 20, the embodiment is different from the embodiment of FIGS. 6 to 19 described above in that the third semiconductor layer SEM3 of the light emitting element LE is omitted. Hereinafter, descriptions of the same components will be simplified or omitted, and differences will be described in detail for descriptive convenience.

The light emitting element LE may include the connection electrode 150, the first semiconductor layer SEM1, the electron blocking layer EBL, the active layer MQW, the superlattice layer SLT, and the second semiconductor layer SEM2. The light emitting element LE may not include the third semiconductor layer SEM3 unlike the above-described embodiment.

The common electrode CE may be disposed on the first via layer VIA1 and the light emitting element LE. The common electrode CE may be in contact with (e.g., in direct contact with) the side surface of the light emitting element LE. For example, the common electrode CE may be in contact with (e.g., in direct contact with) the side surface of the second semiconductor layer SEM2 of the light emitting element LE, and may be spaced apart from the top surface of the second semiconductor layer SEM2. The above-described light emitting element LE may be manufactured as follows. The common electrode CE may be formed on the light emitting element LE including the third semiconductor layer SEM3, and the common electrode CE formed on the top and side surfaces of the third semiconductor layer SEM3 may be exposed by using an organic material layer, thereby partially removing the common electrode CE by a wet etching process. Thereafter, the organic material layer and the third semiconductor layer SEM3 may be etched and removed by a dry etching process to form the structure of the common electrode CE in contact with the side surface of the second semiconductor layer SEM2 of the light emitting element LE as shown in FIG. 20.

The top surface of the second semiconductor layer SEM2 may be aligned with and coincide with the top surface of the common electrode CE and the top surface of the second via layer VIA2. For example, the top surface of the second semiconductor layer SEM2, the top surface of the common electrode CE, and the top surface of the second via layer VIA2 may be flat. Further, the first capping layer CAP1 may be disposed on the second via layer VIA2, the common electrode CE, and the second semiconductor layer SEM2 to be in contact therewith (e.g., in direct contact therewith).

In an embodiment, the third semiconductor layer SEM3 having a high contact resistance with the common electrode CE may be removed and the common electrode CE and the second semiconductor layer SEM2 may be in contact with each other, thereby improving the luminous efficiency of the light emitting element LE.

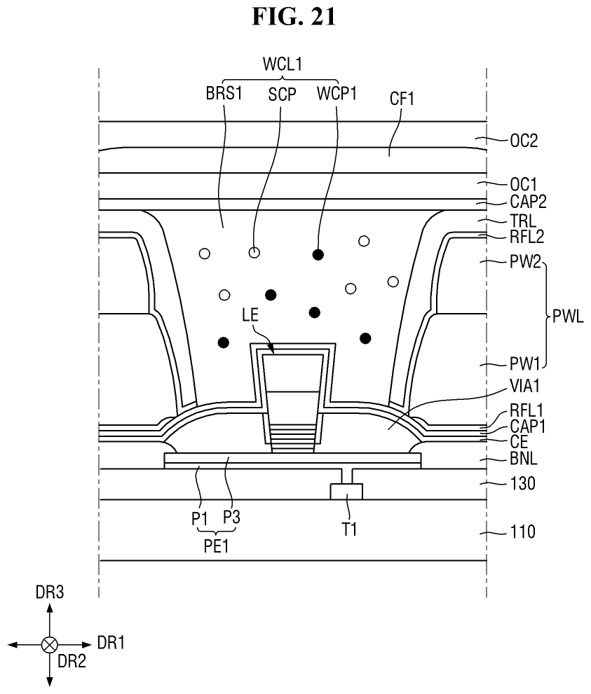

FIG. 21 is a schematic cross-sectional view illustrating a pixel electrode and a light emitting element according to an embodiment.

Referring to FIG. 21, the embodiment is different from the above-described embodiment of FIGS. 6 to 20 in that the second via layer VIA2 is omitted. Hereinafter, descriptions of the same components will be simplified or omitted, and differences will be described in detail for descriptive convenience.

The first capping layer CAP1 may be disposed (e.g., directly disposed) on the common electrode CE. Since the second via layer VIA2 is omitted, the first capping layer CAP1 may be disposed in contact with (e.g., in direct contact with) the entire top surface of the common electrode CE. Further, the first capping layer CAP1 may surround the side surface of the light emitting element LE. In an embodiment, the wavelength conversion layer QDL disposed on the light emitting element LE may be generally made of an organic material, so that the second via layer VIA2 may be omitted.

Hereinafter, a manufacturing process of the display device 10 according to an embodiment will be described with reference to other drawings.

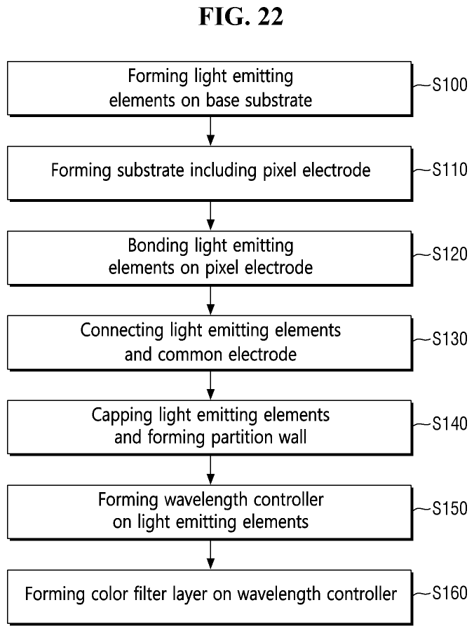

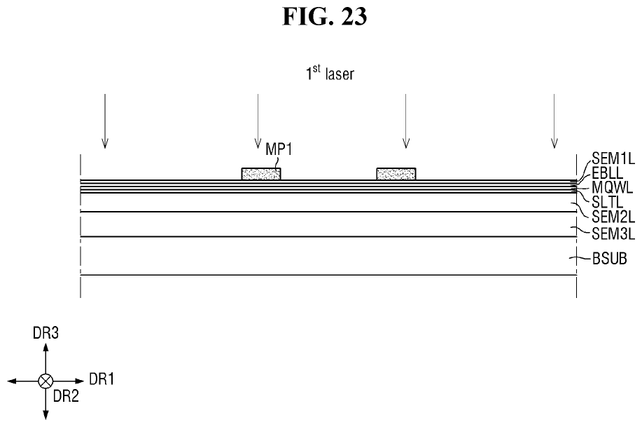

FIG. 22 is a flowchart illustrating a method of manufacturing a display device according to an embodiment. FIGS. 23 to 45 are diagrams illustrating a method of manufacturing a display device according to an embodiment.

FIGS. 23 to 45 are schematic cross-sectional views illustrating structures corresponding to the sequence of formation of the respective layers of the display device 10. FIGS. 23 to 45 illustrate manufacturing processes of the light emitting element unit LEP, the wavelength controller 200, and the color filter layer CFL, and they may generally correspond to the cross-sectional view of FIG. 6. Further, hereinafter, the first emission area EA1 and the second emission area EA2 of the display device 10 will be described. Hereinafter, a method of manufacturing the display device shown in FIGS. 23 to 45 will be described in conjunction with FIG. 22.

Referring to FIG. 22, the method of manufacturing the display device 10 according to an embodiment may include forming light emitting elements on a base substrate (step S100), forming a substrate including a pixel electrode (step S110), bonding the light emitting elements on the pixel electrode (step S120), connecting the light emitting elements and the common electrode (step S130), capping the light emitting elements and forming a definition wall (step S140), forming a wavelength controller on the light emitting elements (step S150), and forming a color filter layer on the wavelength controller (step S160).

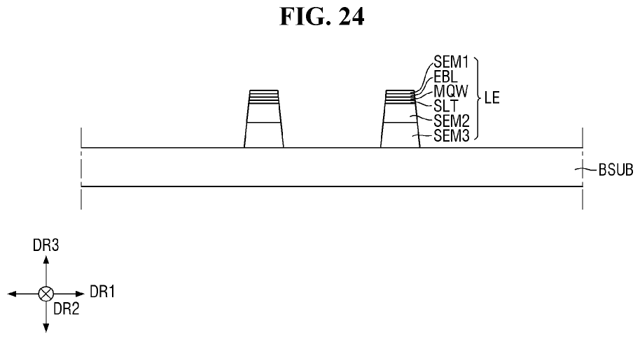

First, referring to FIGS. 23 and 24, the light emitting elements LE may be formed on a base substrate BSUB.

For example, the base substrate BSUB may be prepared or provided. The base substrate BSUB may be a sapphire substrate (Al₂O₃) or a silicon wafer including silicon. However, embodiments are not limited thereto, and in an embodiment, a case in which the base substrate BSUB is a sapphire substrate will be described as an example.

Semiconductor material layers SEM3L, SEM2L, SLTL, MQWL, EBLL, and SEM1L may be formed on the base substrate BSUB. The semiconductor material layers grown by an epitaxial method may be formed by growing seed crystals. For example, the semiconductor material layer may be formed by using one of electron beam deposition, physical vapor deposition (PVD), chemical vapor deposition (CVD), plasma laser deposition (PLD), dual-type thermal evaporation, sputtering, and metal organic chemical vapor deposition (MOCVD) by using the metal organic chemical vapor deposition (MOCVD). However, embodiments are not limited thereto.

For example, a precursor material for forming the semiconductor material layers may be selected to form a target material in a typically selectable range without any limitation. For example, the precursor material may be a metal precursor including an alkyl group such as a methyl group or an ethyl group. Examples of the precursor material may include trimethylgallium Ga(CH₃)₃, trimethylaluminum Al(CH₃)₃, and triethyl phosphate (C₂H₅)₃PO₄ but embodiments are not limited thereto.

For example, the third semiconductor material layer SEM3L may be formed on the base substrate BSUB. Although it is shown in the drawing that a single third semiconductor layer SEM3 is deposited, embodiments are not limited thereto, and layers may be formed. The third semiconductor material layer SEM3L may reduce a lattice constant difference between the second semiconductor material layer SEM2L and the base substrate BSUB. As an example, the third semiconductor material layer SEM3L may include an undoped semiconductor, and may be a material not doped with an n-type or p-type. In an embodiment, the third semiconductor material layer SEM3L may be at least one of undoped InAlGaN, GaN, AlGaN, InGaN, AlN, or InN, but embodiments are not limited thereto.

The second semiconductor material layer SEM2L, the superlattice layer SLTL, the active material layer MQWL, the electron blocking material layer EBLL, and the first semiconductor material layer SEM1L may be sequentially formed on the third semiconductor material layer SEM3L by the above-described method.

For example, the semiconductor material layers SEM3L, SEM2L, SLTL, MQWL, EBLL, and SEM1L may be etched to form the light emitting elements LE.

For example, first mask pattern members MP1 may be formed on the first semiconductor material layer SEM1L. The first mask pattern member MP1 may be a hard mask including an inorganic material or a photoresist mask including an organic material. The first mask pattern member MP1 may prevent the semiconductor material layers SEM3L, SEM2L, SLTL, MQWL, EBLL, and SEM1L disposed therebelow from being etched. For example, the light emitting elements LE may be formed by partially etching (e.g., 1^{st} etch) the semiconductor material layers by using the first mask pattern members MP1 as a mask.

As illustrated in FIG. 24, the semiconductor material layers SEM3L, SEM2L, SLTL, MQWL, EBLL, and SEM1L that do not overlap the first mask pattern member MP1 may be etched and removed on the base substrate BSUB, and a portion that is not etched by overlapping with the first mask pattern member MP1 may be the light emitting elements LE.

The semiconductor material layers may be etched by a conventional method. For example, the process of etching the semiconductor material layers may be performed by a dry etching method, a wet etching method, a reactive ion etching (RIE) method, a deep reactive ion etching (DRIE) method, an inductively coupled plasma reactive ion etching (ICP-RIE) method, or the like. The dry etching method may be suitable for vertical etching because anisotropic etching is performed. In the case of using the aforementioned etching technique, Cl₂ or O₂ may be used as an etchant. However, embodiments are not limited thereto.

The semiconductor material layers SEM3L, SEM2L, SLTL, MQWL, EBLL, and SEM1L overlapping the first mask pattern member MP1 may not be etched and may be formed as the light emitting elements LE. Accordingly, the light emitting elements LE may be formed by including the third semiconductor layer SEM3, the second semiconductor layer SEM2, the superlattice layer SLT, the active layer MQW, the electron blocking layer EBL, and the first semiconductor layer SEM1.

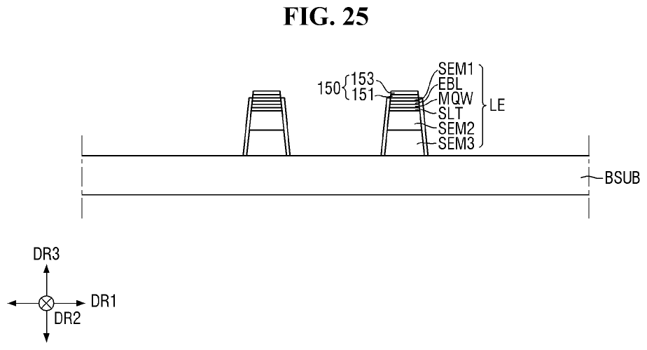

Referring to FIG. 25, the connection electrodes 150 may be formed on the light emitting elements LE by stacking connection electrode material layers on the base substrate BSUB and etching them.

For example, the connection electrode 150 including the reflective layer 151 and the connection layer 153 may be formed by sequentially stacking a reflective layer material layer and a connection layer material layer on the base substrate BSUB and etching them simultaneously. The connection electrode 150 may be formed (e.g., directly formed) on the top surface of the first semiconductor layer SEM1 of the light emitting element LE. In an embodiment, the reflective layer 151 of the connection electrode 150 may be in contact with (e.g., in direct contact with) the top surface of the first semiconductor layer SEM1 of the light emitting element LE. The light emitting element LE may include the connection electrode 150.

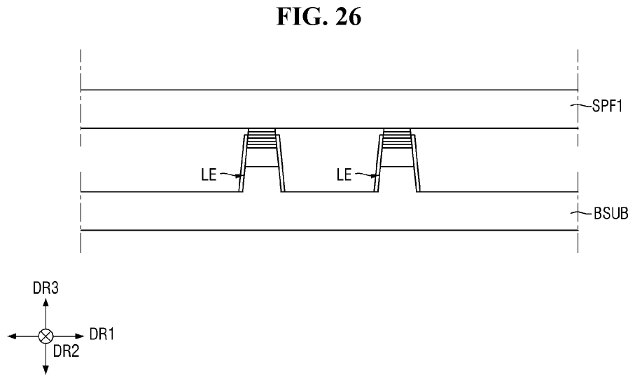

Referring to FIG. 26, a first support film SPF1 may be attached on the light emitting elements LE of the base substrate BSUB manufactured in FIG. 25.

For example, the first support film SPF1 may be attached on the light emitting elements LE. The first support film SPF1 may be aligned on the light emitting elements LE, and may be attached to each connection electrode 150 of the light emitting elements LE. The light emitting elements LE may be disposed in large numbers, and thus may be attached to the first support film SPF1 without being detached.

The first support film SPF1 may include a support layer and an adhesive layer disposed on the support layer. The support layer may be made of a material that is transparent and has mechanical stability to allow light to pass therethrough. For example, the support layer may include a transparent polymer such as polyester, polyacrylic, polyepoxy, polyethylene, polystyrene, polyethylene terephthalate, or the like. The adhesive layer may include an adhesive material for the adhesion of the light emitting element LE. For example, the adhesive material may include urethane acrylates, epoxy acrylates, polyester acrylates, or the like. The adhesive material may be a material whose adhesive strength changes as ultraviolet (UV) or heat is applied, and thus the adhesive layer may be readily separated from the light emitting element LE.

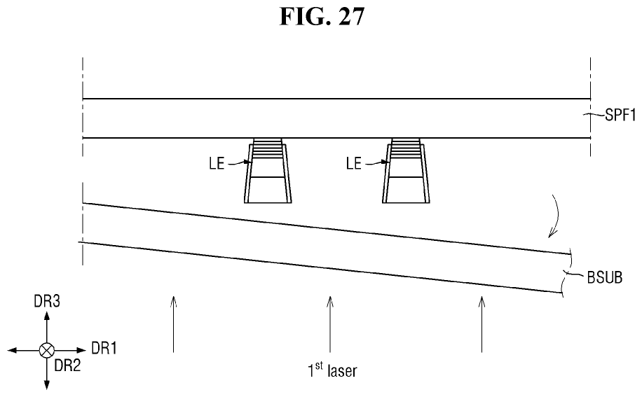

Referring to FIG. 27, the base substrate BSUB may be separated by irradiating the base substrate BSUB with laser (e.g., 1^{st} laser). The base substrate BSUB may be separated from each of the third semiconductor layers SEM3 of the light emitting elements LE.

The process of separating the base substrate BSUB may be a laser lift off (LLO) process. In the laser lift off process by using laser, KrF excimer laser (e.g., about 248 nm wavelength) may be used as a source. The energy density of the excimer laser may be irradiated in the range of about 550 mJ/cm² to about 950 mJ/cm², and the incident area may be in the range of about 50×50 μm² to about 1×1 cm², but embodiments are not limited thereto. By irradiating the laser to the base substrate BSUB, the base substrate BSUB may be separated from the light emitting element LE.

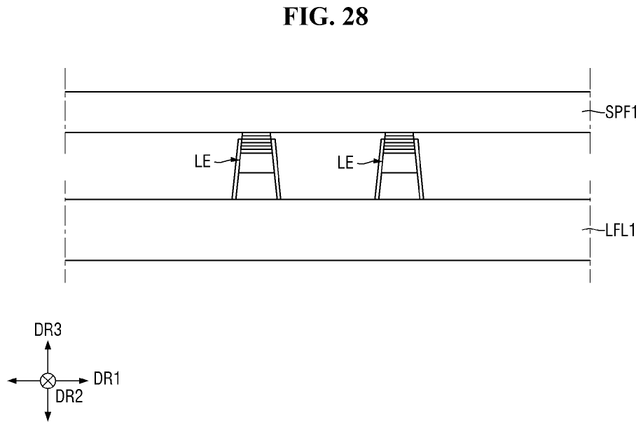

Referring to FIG. 28, the first transfer film LFL1 may be attached to the light emitting elements LE from which the base substrate BSUB is separated.

For example, the first transfer film LFL1 may be attached on each of the third semiconductor layers SEM3 of the light emitting elements LE. The first transfer film LFL1 may be aligned on the light emitting elements LE and may be attached to each of the third semiconductor layers SEM3 of the light emitting elements LE.

The first transfer film LFL1 may include a stretchable material. The stretchable material may include, e.g., polyolefine, polyvinyl chloride (PVC), elastomeric silicone, elastomeric polyurethane, elastomeric polyisoprene, or the like. Like the above-described first support film SPF1, the first transfer film LFL1 may also include a support layer and an adhesive layer to adhere and support the light emitting elements LE.

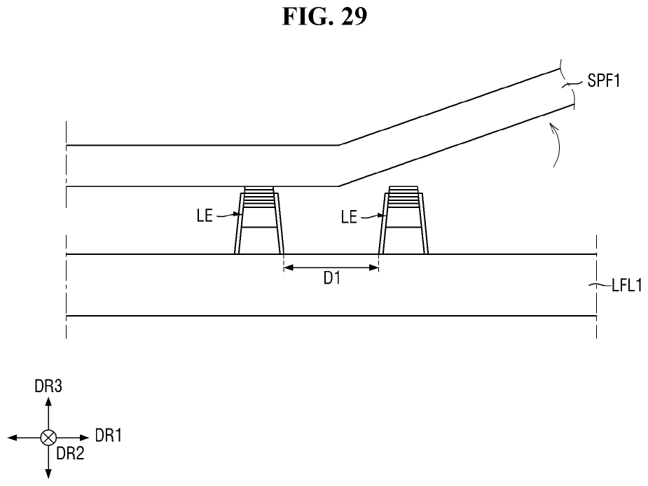

Referring to FIG. 29, the first support film SPF1 may be separated from the light emitting elements LE. After ultraviolet (UV) or heat is applied to the first support film SPF1 to reduce the adhesive strength of the adhesive layer of the first support film SPF1, the first support film SPF1 may be physically or smoothly separated. The light emitting elements LE may be spaced apart from each other by a certain first interval (or first distance) D1 on the first transfer film LFL1 to be arranged in a dot shape.

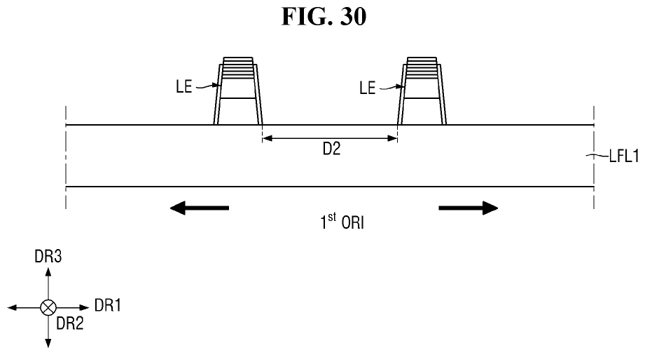

Referring to FIG. 30, the first transfer film LFL1 may be stretched (e.g., 1^{st} ORI). The first transfer film LFL1 may be stretched two-dimensionally in the first direction DR1 and the second direction DR2. Since the first transfer film LFL1 is stretched, the interval (or distance) between the light emitting elements LE attached on the first transfer film LFL1 may be a second interval (or second distance) D2 larger than the interval (or first distance) D1 of FIG. 29. The stretching strength (or tensile strength) of the first transfer film LFL1 may be adjusted according to the desired interval (or distance) of the light emitting elements LE, and may be, for example, about 120 gf/inch. However, embodiments are not limited thereto.

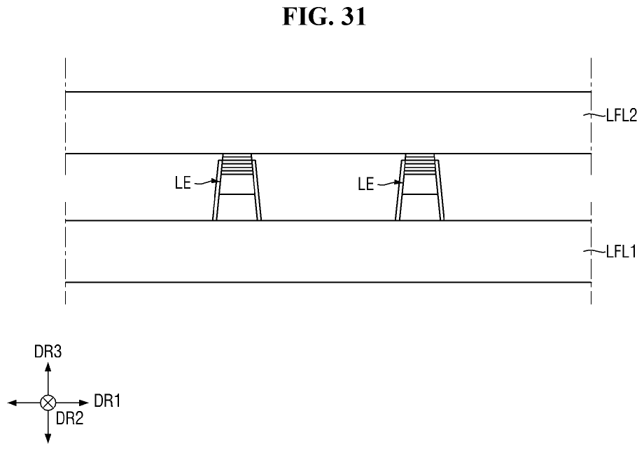

Referring to FIG. 31, a second transfer film LFL2 may be attached on the light emitting elements LE from which the first support film SPF1 is separated. The second transfer film LFL2 may be aligned on the light emitting elements LE, and may be attached on each connection electrode 150 of the light emitting elements LE. The second transfer film LFL2 may include the support layer and the adhesive layer, similar to the above-described first transfer film LFL1, and a detailed description thereof has been made, so that the description thereof will be omitted for descriptive convenience.

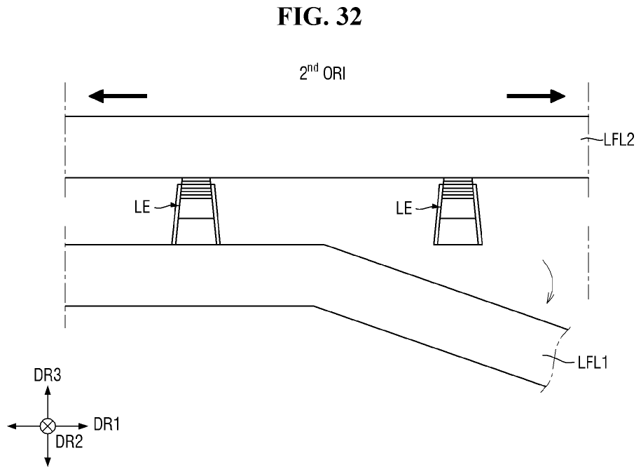

Referring to FIG. 32, the first transfer film LFL1 may be separated from the light emitting elements LE. After UV or heat is applied to the first transfer film LFL1 to reduce the adhesive strength of the adhesive layer of the first transfer film LFL1, the first transfer film LFL1 may be physically or smoothly separated.

For example, the second transfer film LFL2 may be stretched (e.g., 2^{nd} ORI). The second transfer film LFL2 may be stretched two-dimensionally in the first direction DR1 and the second direction DR2. Since the second transfer film LFL2 is stretched, the interval (or distance) between the light emitting elements LE attached on the second transfer film LFL2 may be further increased. The stretching strength (or tensile strength) of the second transfer film LFL2 may be adjusted according to the desired interval (or distance) of the light emitting elements LE, and may be, for example, about 270 gf/inch. However, embodiments are not limited thereto.

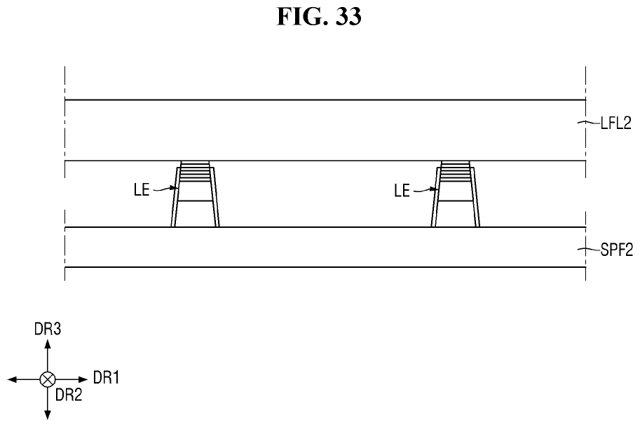

Referring to FIG. 33, a second support film SPF2 may be attached on the light emitting elements LE from which the first transfer film LFL1 is separated. The second support film SPF2 may be aligned on the light emitting elements LE and may be attached to each of the third semiconductor layers SEM3 of the light emitting elements LE. The second support film SPF2 may include the support layer and the adhesive layer, similar to the above-described first support film SPF1, and a detailed description thereof has been made, so that the description thereof will be omitted for descriptive convenience.

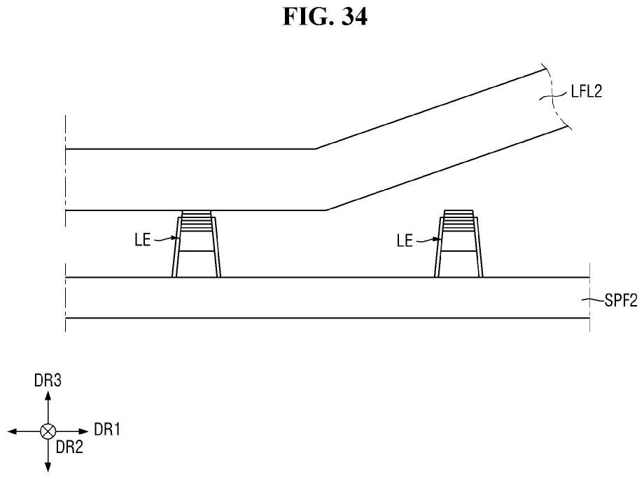

Referring to FIG. 34, the second transfer film LFL2 may be separated. For example, the second transfer film LFL2 attached to the connection electrode 150 of the light emitting elements LE may be separated. Since the separation process of the second transfer film LFL2 is the same as that of the separation of the above-described first transfer film LFL1, the description thereof will be omitted for descriptive convenience. The second transfer film LFL2 may be separated and removed from the connection electrodes 150 of the light emitting elements LE.

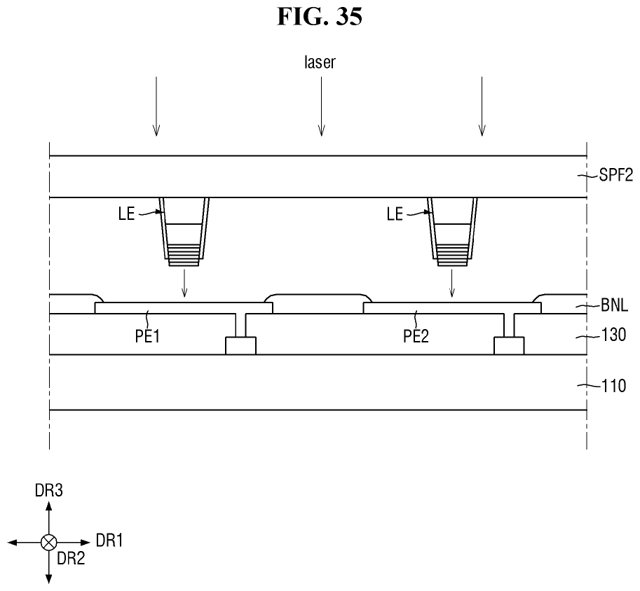

Referring to FIG. 35, the second support film SPF2 may be arranged over the substrate 110, and the light emitting elements LE may be adhered on the pixel electrodes PE1 and PE2.

For example, the second support film SPF2 may be aligned on the substrate 110. For example, the connection electrode 150 of the light emitting element LE formed on the second support film SPF2 may be aligned to face the substrate 110.

For example, the substrate 110 and the second support film SPF2 may be bonded. For example, the connection electrode 150 of the light emitting element LE formed on the second support film SPF2 may be moved into contact with the pixel electrodes PE1 and PE2 of the substrate 110. For example, the connection layer 153 of the light emitting element LE may be moved into contact with the pixel electrodes PE1 and PE2. For example, the substrate 110 and the second support film SPF2 may be bonded by fusion bonding the connection layer 153 of the light emitting element LE and the pixel electrodes PE1 and PE2. For example, the light emitting elements LE may be adhered to the top surfaces of the pixel electrodes PE1 and PE2. In the fusion bonding process, laser may be irradiated to the pixel electrodes PE1 and PE2 from a position above the second support film SPF2. High heat of the laser may be transferred to the pixel electrodes PE1 and PE2 irradiated with the laser, so that the interfaces between the connection layer 153 of the light emitting element LE and the pixel electrodes PE1 and PE2 may be adhered. For example, the upper electrode layers P3 of the pixel electrodes PE1 and PE2 may be made of copper (Cu) having excellent thermal conductivity, and thus may have an excellent adhesion property with the connection layer 153 of the light emitting element LE. Yttrium aluminum garnet (YAG) laser may be used as the source of the laser used for fusion bonding process.

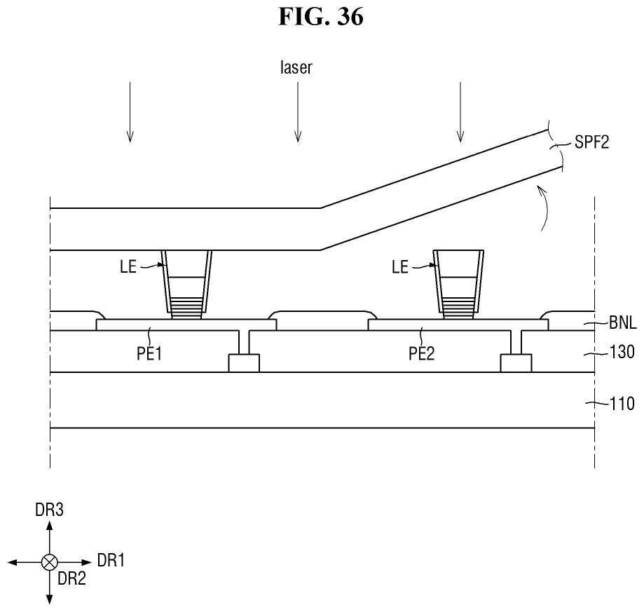

Referring to FIG. 36, the second support film SPF2 may be separated from the light emitting elements LE.

For example, the second support film SPF2 may be separated from the third semiconductor layer SEM3 of the light emitting element LE. The process of separating the second support film SPF2 may be a laser lift off (LLO) process. In the laser lift off process by using laser, KrF excimer laser (e.g., about 248 nm wavelength) may be used as a source. The energy density of the excimer laser may be irradiated in the range of about 550 mJ/cm² to about 950 mJ/cm², and the incident area may be in the range of about 50×50 μm² to about 1×1 cm², but embodiments are not limited thereto. By irradiating the laser to the second support film SPF2, the second support film SPF2 may be separated from the light emitting element LE. For another example, the process of separating the second support film SPF2 may be a physical separation process other than the laser lift off process. Since the bonding force between the second support film SPF2 and the light emitting element LE is weaker than the bonding force between the connection layer 153 of the light emitting element LE and the pixel electrodes PE1 and PE2 that are fusion-bonded, the second support film SPF2 may be physically separated due to the difference in the adhesive strength.

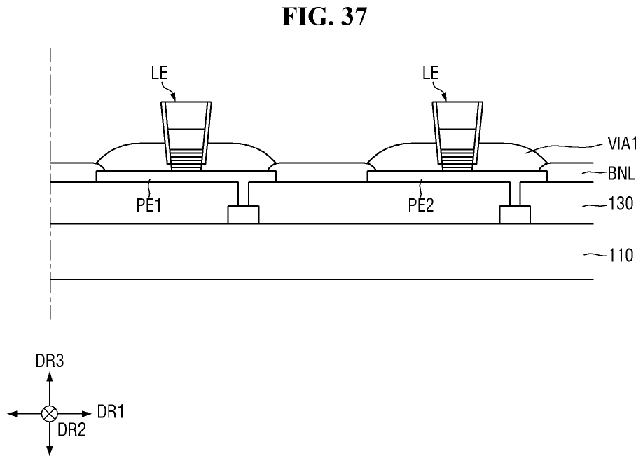

Referring to FIG. 37, the first via layer VIA1 may be formed on the substrate 110 on which the light emitting elements LE are formed. The first via layer VIA1 may be formed on the pixel electrodes PE1 and PE2 and the bank layer BNL. The first via layers VIA1 may be disposed on the emission areas EA1 and EA2 and may be spaced apart from each other between the adjacent emission areas EA1 and EA2. The first via layer VIA1 may be formed by applying a solution by using a solution process such as spin coating or inkjet printing and patterning it by an exposure process. The first via layer VIA1 may have a height lower than the height of the second semiconductor layer SEM2 of the light emitting element LE.

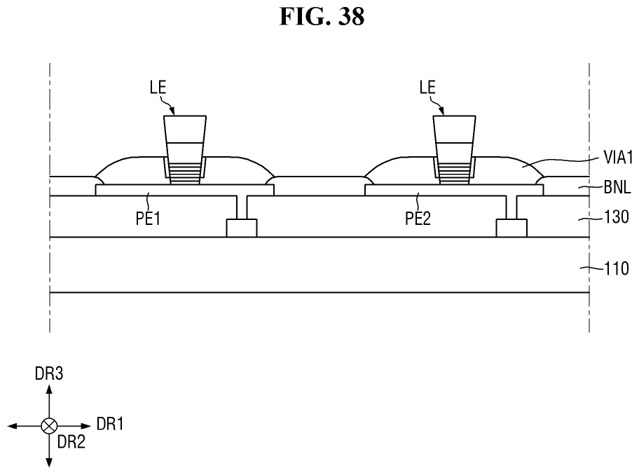

Referring to FIG. 38, the insulating layer INS of the light emitting element LE may be etched by using the first via layer VIA1 as a mask. The insulating layer INS may be etched by a wet etching process, and may be etched by using a buffered oxide etchant (BOE) etchant, for example. The insulating layer INS exposed to the outside of the first via layer VIA1 may be etched and removed. Accordingly, a portion of the side surface of the second semiconductor layer SEM2 and the third semiconductor layer SEM3 of the light emitting element LE may be exposed.

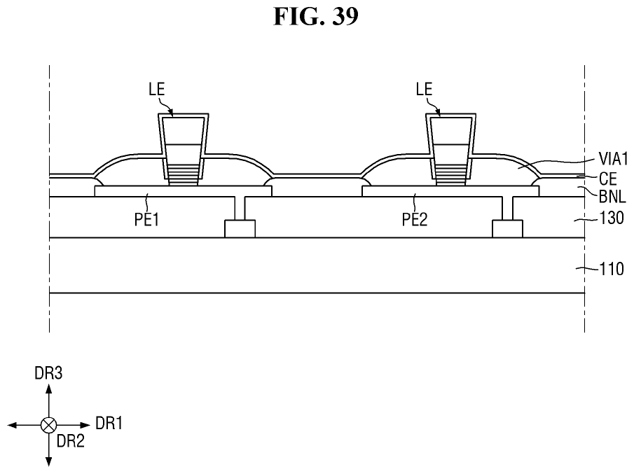

Referring to FIG. 39, the common electrode CE may be formed on the light emitting elements LE, and the light emitting elements LE and the common electrode CE may be connected. The common electrode CE may be continuously formed in the entire display area. The common electrode CE may cover the bank layer BNL, the first via layer VIA1, the insulating layer INS, and the light emitting element LE, and may be in contact therewith (e.g., in direct contact therewith). For example, the common electrode CE may be in contact with (e.g., in direct contact with) the side surface of the second semiconductor layer SEM2 of the light emitting element LE that is exposed by removing the insulating layer INS, and the top and side surfaces of the third semiconductor layer SEM3.

For example, in another example, the surface treatment of the light emitting element LE may be further performed before the common electrode CE is formed. The surface treatment may be performed to control defects on the side surface of the light emitting element LE damaged during the etching process of the insulating layer INS. In the surface treatment, the surface of the light emitting element LE may be treated with potassium hydroxide (KOH), for example. However, embodiments are not limited thereto.

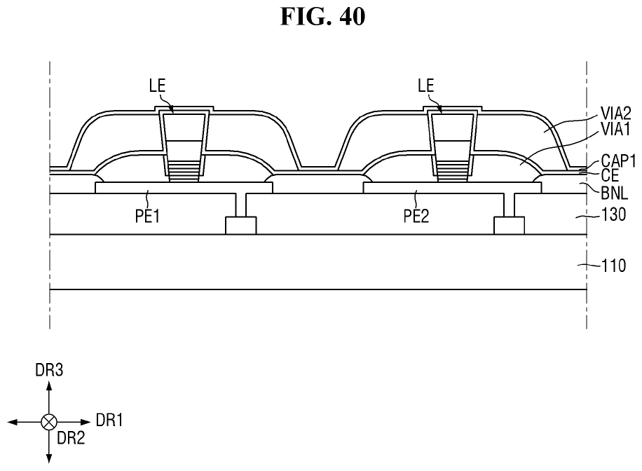

Referring to FIG. 40, the light emitting elements LE may be capped (or covered) by forming the first capping layer CAP1 on the substrate 110 on which the common electrode CE is formed. The first capping layer CAP1 may be formed by stacking an inorganic insulating material by a physical vapor deposition method, a chemical vapor deposition method, or the like. The first capping layer CAP1 may be continuously formed in the entire display area of the substrate 110.

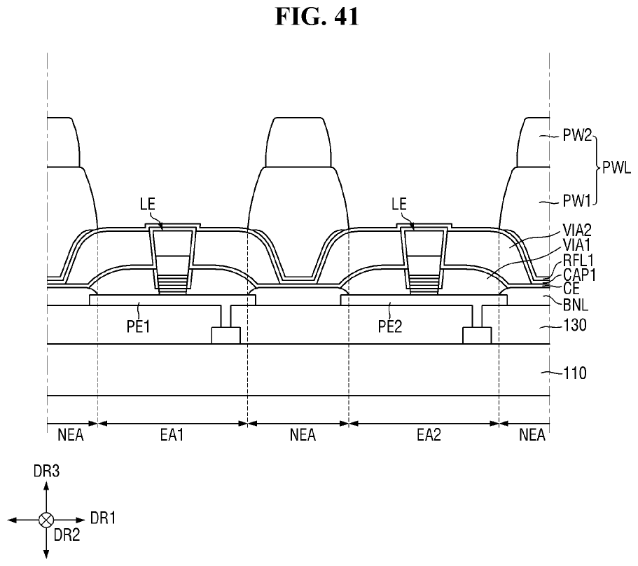

Referring to FIG. 41, the first reflective layer RFL1 may be formed on the first capping layer CAP1. The first reflective layer RFL1 may overlap the bank layer BNL and may be formed in a grid shape extending in the first direction DR1 and the second direction DR2.

The definition wall PWL may be formed by stacking the first definition wall PW1 and the second definition wall PW2 on the first reflective layer RFL1. An organic material including a light blocking material may be coated by a solution process and patterned to form the first definition wall PW1, and an organic material including a light blocking material may be coated on the substrate 110 on which the first definition wall PW1 is formed by a solution process and patterned to form the second definition wall PW2 stacked on the first definition wall PW1. The definition wall PWL may overlap the first reflective layer RFL1, and may be formed in a grid shape extending in the first direction DR1 and the second direction DR2. The definition wall PWL may partition (or define) the emission areas EA1 and EA2 where light emitted from the light emitting element LE is emitted and the non-emission area NEA where light is not emitted.

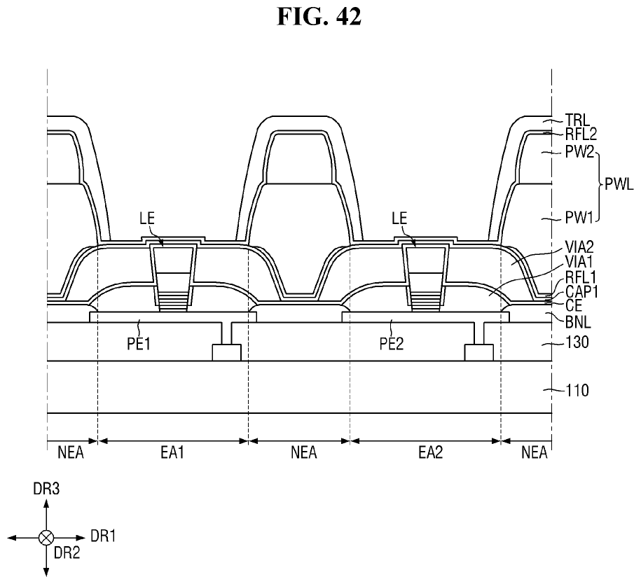

Referring to FIG. 42, a reflective metal material layer RFLL may be stacked on the substrate 110 on which the definition wall PWL is formed, and the cover layer TRL covering the definition wall PWL may be formed. The reflective metal material layer RFLL may be in contact with (e.g., in direct contact with) the first capping layer CAP1 and the definition wall PWL. The cover layer TRL may be formed in the region overlapping the definition wall PWL and may cover a portion of the reflective metal material layer RFLL.

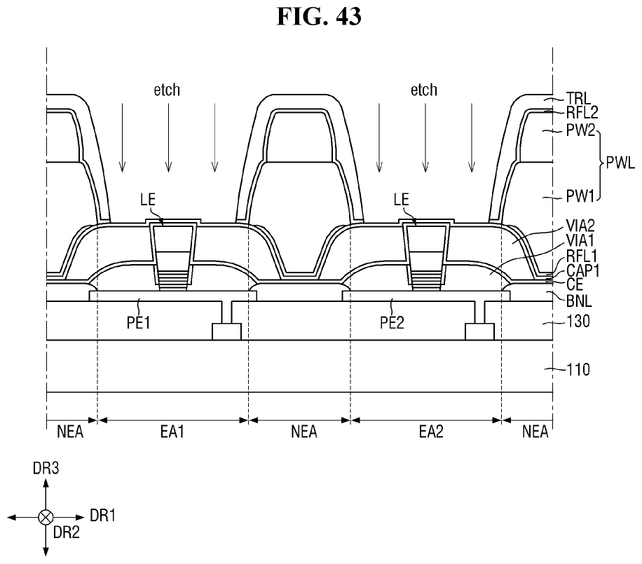

Referring to FIG. 43, the reflective metal material layer RFLL may be etched by the cover layer TRL as a mask to form the second reflective layer RFL2. The second reflective layer RFL2 may be etched by the cover layer TRL as a mask, so that the side surface of the second reflective layer RFL2 and the side surface of the cover layer TRL may be aligned with each other.

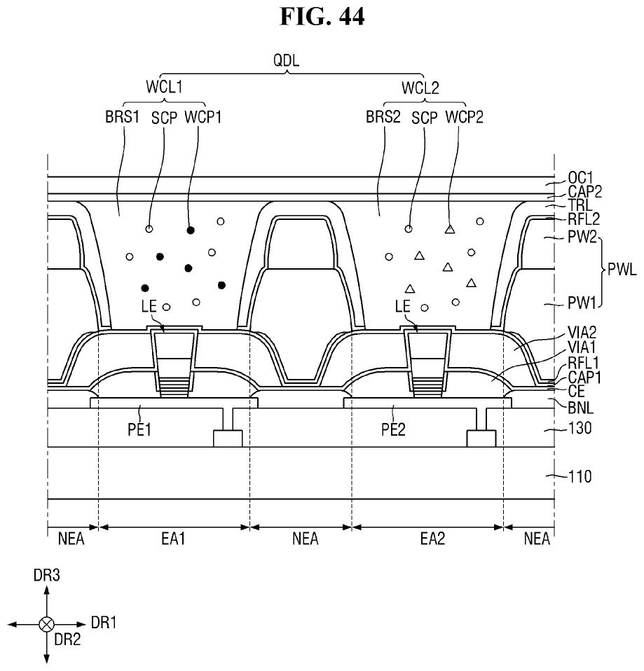

Referring to FIG. 44, the wavelength conversion layer QDL may be formed in the space partitioned (or defined) by the definition wall PWL and the cover layer TRL.

For example, the first wavelength conversion pattern member WCL1 may be formed in the first emission area EA1 and the second wavelength conversion pattern member WCL2 may be formed in the second emission area EA2. The first wavelength conversion pattern member WCL1 and the second wavelength conversion pattern member WCL2 may fill the spaces partitioned (or defined) by the definition wall PWL and the cover layer TRL. The first wavelength conversion pattern member WCL1 may be formed of a solution in which the first wavelength conversion particle WCP1 and the scatterer SCP may be mixed in the first base resin BRS1 by a solution process such as inkjet printing, imprinting, or the like, but embodiments are not limited thereto. The second wavelength conversion pattern member WCL2 may also be formed of a solution in which the second wavelength conversion particle WCP2 and the scatterer SCP are mixed in the second base resin BRS2. For example, the wavelength conversion layer QDL may include the light transmission pattern member TPL (see FIG. 6) in the third emission area EA3 (see FIG. 6) adjacent to the second emission area EA2.

For example, the second capping layer CAP2 may be stacked on the first wavelength conversion pattern member WCL1, the second wavelength conversion pattern member WCL2, and the cover layer TRL. The first overcoat layer OC1 may be formed on the second capping layer CAP2.

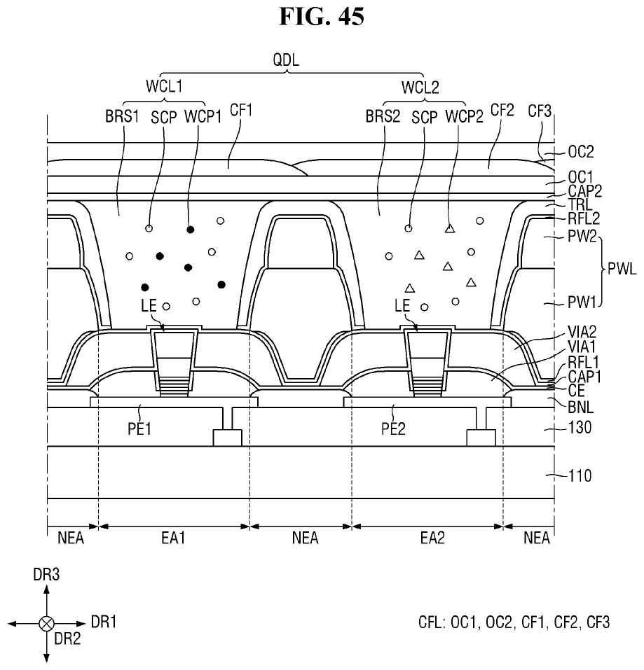

Referring to FIG. 45, the color filter layer CFL may be formed on the first overcoat layer OC1.

For example, a first color filter material may be applied on the first overcoat layer OC1. The first color filter CF1 corresponding to the first emission area EA1 may be formed by a photo process. For example, a second color filter material may be applied and the second color filter CF2 corresponding to the second emission area EA2 may be formed by a photo process. For example, the third color filter CF3 adjacent to the second color filter CF2 may be formed. Each of the color filters CF1, CF2, and CF3 may have a thickness of about 1 μm or less, but embodiments are not limited thereto.

For example, the second overcoat layer OC2 may be formed on the color filter layer CFL, thereby manufacturing the display device 10 according to an embodiment.

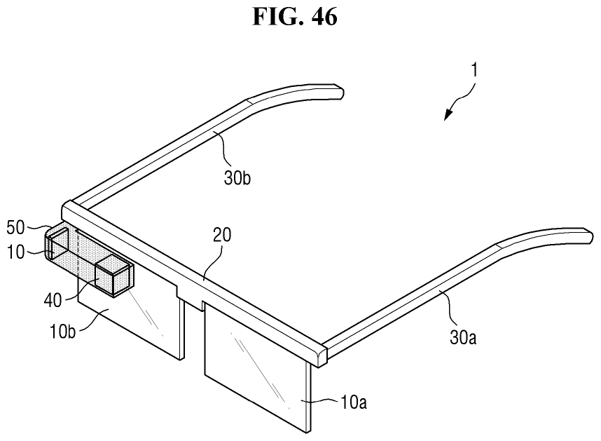

FIG. 46 is a schematic diagram illustrating a virtual reality device including a display device according to an embodiment. FIG. 46 illustrates a virtual reality device 1 to which the display device 10 according to an embodiment is applied.

Referring to FIG. 46, the virtual reality device 1 according to an embodiment may be a glass-type device. The virtual reality device 1 according to an embodiment may include the display device 10, a left lens 10a, a right lens 10b, a support frame 20, temples 30a and 30b, a reflection member 40, and a display device storage 50.

Although FIG. 46 illustrates the virtual reality device 1 including the temples 30a and 30b, the virtual reality device 1 according to an embodiment may be applied to a head mounted display including a head mounted band that may be worn on a head, instead of the temples 30a and 30b. For example, the virtual reality device 1 according to an embodiment is not limited to that shown in FIG. 46, and may be applied in various forms to various electronic devices.

The display device storage 50 may include the display device 10 and the reflection member 40. The image displayed on the display device 10 may be reflected by the reflection member 40 and provided to a user's right eye through the right lens 10b. Accordingly, the user may view (or recognize) the virtual reality image displayed on the display device 10 through the right eye.

FIG. 46 illustrates that the display device storage 50 is disposed at the end portion of the right side of a support frame 20, but embodiments are not limited thereto. For example, the display device storage 50 may be disposed at the left end portion of the support frame 20, and the image displayed on the display device 10 may be reflected by the reflection member 40 and provided to a user's left eye through the left lens 10a. Accordingly, the user may view (or recognize) the virtual reality image displayed on the display device 10 through the left eye. In another example, the display device storage 50 may be disposed at both the left end portion and the right end portion of the support frame 20. For example, the user may view (or recognize) the virtual reality image displayed on the display device 10 through both the left eye and the right eye.

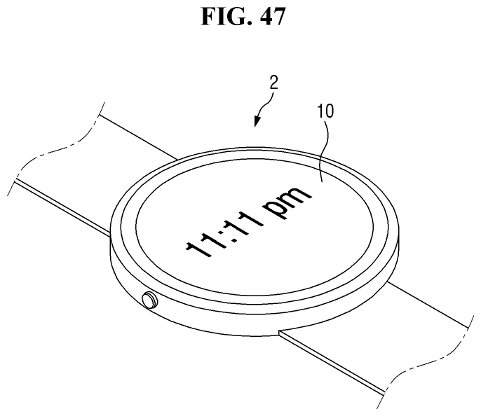

FIG. 47 is a schematic diagram illustrating a smart device including a display device according to an embodiment.

Referring to FIG. 47, the display device 10 according to an embodiment may be applied to the smart watch 2 that is one of the smart devices.

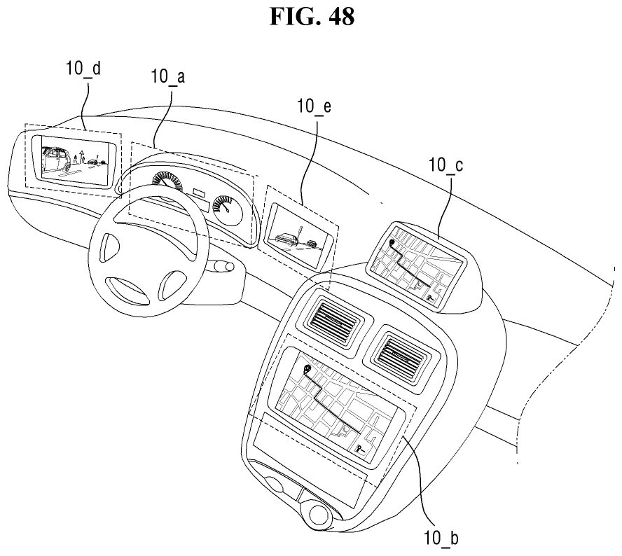

FIG. 48 is a schematic diagram illustrating an automobile including a display device according to an embodiment. FIG. 48 shows an automobile to which the display device 10 according to an embodiment is applied.

Referring to FIG. 48, the display devices 10_a, 10_b, and 10_c according to an embodiment may be applied to the dashboard of the automobile, the center fascia of the automobile, or the center information display (CID) of the dashboard of the automobile. Further, the display devices 10_d, and 10_e according to an embodiment may be applied to a room mirror display instead of side mirrors of the automobile.

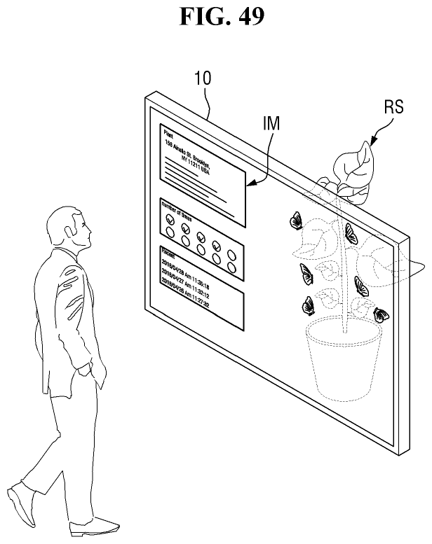

FIG. 49 is a schematic diagram illustrating a transparent display device including a display device according to an embodiment.

Referring to FIG. 49, the display device 10 according to an embodiment may be applied to the transparent display device. The transparent display device may display an image IM, and also may transmit light. Thus, a user positioned on the front side of the transparent display device may view (or see) an object RS or a background on the rear side of the transparent display device as well as the image IM displayed on the display device 10. In case that the display device 10 is applied to the transparent display device, the substrate 110 of the display device 10 shown in FIG. 6 may include a light transmitting portion capable of transmitting light or may be made of a material capable of transmitting light.

In concluding the detailed description, those skilled in the art will appreciate that many variations and modifications may be made to the embodiments without substantially departing from the principles of the invention. Therefore, the disclosed embodiments are used in a generic and descriptive sense only and not for purposes of limitation.

What is claimed is:

1. A display device comprising:
a pixel electrode disposed on a substrate;
light emitting elements disposed on the pixel electrode;
a first via layer disposed on the pixel electrode and filled between the light emitting elements; and
a common electrode disposed on the first via layer and the light emitting elements, wherein
each of the light emitting elements comprises:
a first semiconductor layer including a p-type dopant,
an active layer disposed on the first semiconductor layer,
a second semiconductor layer disposed on the active layer and including an n-type dopant, and
a third semiconductor layer disposed on the second semiconductor layer, and
the common electrode is in contact with a side surface of the second semiconductor layer.

2. The display device of claim 1, wherein
each of the light emitting elements comprises an insulating layer surrounding an outer circumferential surface of each of the first semiconductor layer, the active layer, the second semiconductor layer and the third semiconductor layer,
the insulating layer exposes a portion of the outer circumferential surface of the second semiconductor layer, and
the common electrode is in contact with the portion of the outer circumferential surface of the second semiconductor layer exposed by the insulating layer.

3. The display device of claim 1, wherein
in a longitudinal direction of the light emitting elements, a length of the side surface of the second semiconductor layer in contact with the common electrode is about 10% or more of a thickness of the second semiconductor layer.

4. The display device of claim 1, wherein
the common electrode is in contact with a top surface and a side surface of the third semiconductor layer.

5. The display device of claim 1, further comprising:
a second via layer disposed on the common electrode and filled between the light emitting elements,
wherein a top surface of the second via layer and a top surface of the third semiconductor layer are aligned with each other.

6. The display device of claim 1, wherein
the common electrode is in contact with a side surface of the third semiconductor layer and is spaced apart from a top surface of the third semiconductor layer.

7. The display device of claim 6, wherein
a top surface of the common electrode and the top surface of the third semiconductor layer are aligned with each other.

8. The display device of claim 1, wherein
the common electrode is spaced apart from the third semiconductor layer, and
a top surface of the common electrode and a top surface of the second semiconductor layer are aligned with each other.

9. The display device of claim 1, wherein
a top surface of the third semiconductor layer comprises a plurality of grooves recessed toward the second semiconductor layer.

10. The display device of claim 1, further comprising:
a wavelength controller disposed on the common electrode, wherein
the wavelength controller comprises definition walls defining emission areas and a non-emission area;
a cover layer disposed on the definition walls; and
a wavelength conversion layer disposed between the definition walls and overlapping the emission areas.

11. The display device of claim 10, wherein
the definition walls comprises a first definition wall and a second definition wall disposed on the first definition wall, and
the first definition wall and the second definition wall include a light blocking material.

12. The display device of claim 10, wherein
the wavelength controller comprises:
a first reflective layer disposed between the common electrode and the definition walls, and
a second reflective layer disposed between the definition walls and the cover layer, and
the first reflective layer and the second reflective layer overlap the non-emission area.

13. The display device of claim 10, further comprising:
a color filter layer disposed on the wavelength controller,
wherein the color filter layer comprises:
a first color filter that transmits first light,
a second color filter that transmits second light, and
a third color filter that transmits third light.

14. A display device comprising:
a pixel electrode disposed on a substrate;
light emitting elements disposed on the pixel electrode;
a first via layer disposed on the pixel electrode and filled between the light emitting elements;
a common electrode disposed on the first via layer and the light emitting elements; and
a first capping layer disposed on the light emitting elements and the common electrode, wherein
each of the light emitting elements comprises:
a first semiconductor layer including a p-type dopant,
an active layer disposed on the first semiconductor layer, and
a second semiconductor layer disposed on the active layer and including an n-type dopant, and
the common electrode is in contact with a side surface of the second semiconductor layer, and
the first capping layer is in contact with a top surface of the common electrode and a top surface of the second semiconductor layer.

15. The display device of claim 14, further comprising:
a second via layer disposed on the common electrode and filled between the light emitting elements,
wherein a top surface of the second via layer and the top surface of the second semiconductor layer are aligned with each other.

16. The display device of claim 14, wherein
the top surface of the common electrode and the top surface of the second semiconductor layer are aligned with each other.

17. A display device comprising:
a pixel electrode disposed on a substrate;
light emitting elements disposed on the pixel electrode;
a first via layer disposed on the pixel electrode and filled between the light emitting elements; and
a common electrode disposed on the first via layer and the light emitting elements, wherein
each of the light emitting elements comprises:
a first semiconductor layer including a p-type dopant,
an active layer disposed on the first semiconductor layer,
a second semiconductor layer disposed on the active layer and including an n-type dopant, and
a third semiconductor layer disposed on the second semiconductor layer, and
the common electrode is in contact with a side surface of the second semiconductor layer, and
a length of the side surface of the second semiconductor layer in contact with the common electrode is different from a length of another side surface of the second semiconductor layer in contact with the common electrode.

18. The display device of claim 17, further comprising:
a second via layer disposed on the common electrode and filled between the light emitting elements, wherein
a portion of a top surface of the third semiconductor layer overlaps the second via layer, and
another portion of the top surface of the third semiconductor layer does not overlap the second via layer.

19. The display device of claim 17, wherein
the light emitting elements comprise a connection electrode comprising a connection layer disposed between the first semiconductor layer and the pixel electrode, and
a thickness of a portion of the connection layer is different from a thickness of another portion of the connection layer.

20. The display device of claim 17, wherein
the light emitting elements are inclined with respect to a top surface of the pixel electrode.
